(19) United States
(12) Patent Application Publication
(10) Pub. No.: US 2026/0038401 A1
(43) Pub. Date: Feb. 5, 2026

(54) DISPLAY APPARATUS

(71) Applicant: LG Display Co., Ltd., Seoul (KR)

(72) Inventors: Hae Sung LEE, Paju-si (KR); Kyoung June JUNG, Paju-si (KR); Dae Han WON, Paju-si (KR)

(73) Assignee: LG Display Co., Ltd., Seoul (KR)

(21) Appl. No.: 19/253,229

(22) Filed: Jun. 27, 2025

(30) Foreign Application Priority Data
Jul. 30, 2024 (KR) 10-2024-0100738

(51) Int. Cl. G09G 3/00; G09G 3/32; H01L 25/16; H10H 29/37; H10H 29/49; H10H 29/855

(52) U.S. Cl. CPC G09G 3/006; G09G 3/32; H01L 25/167; H10H 29/37; H10H 29/49; H10H 29/855; G09G 2300/0413; G09G 2320/0233; G09G 2330/10; G09G 2330/12

(57) ABSTRACT

A display apparatus includes a plurality of pixel driving circuits and at least one dummy pixel driving circuit disposed apart from each other on a substrate, a plurality of driving wires disposed corresponding to the plurality of pixel driving circuits, and a test wire electrically connected to the dummy pixel driving circuit.

### CROSS-REFERENCE TO RELATED APPLICATION

This application claims priority to and the benefit of Korean Patent Application No. 10-2024-0100738, filed Jul. 30, 2024, the disclosure of which is incorporated herein by reference in its entirety.

### BACKGROUND

### Field

The present specification relates to an apparatus and particularly to, for example, without limitation, a display apparatus.

### Discussion of Related Art

Display devices are applied to various electronic devices such as a television (TV), a mobile phone, a laptop, and a tablet.

The display devices include an organic light emitting display (OLED) that is self-emissive, a liquid crystal display (LCD) that requires a separate light source, and the like.

Recently, a display device including a light-emitting element (e.g., a light-emitting diode; LED) has been attracting attention as a next-generation display device. Since the light-emitting element is formed of an inorganic material rather than an organic material, the light-emitting element has a faster lighting speed, superior luminous efficiency, and can display an image with high luminance compared to the LCD or the OLED.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

A pixel driving circuit for driving a light-emitting element may be disposed in a display panel. Since a plurality of pixel driving circuits are configured on one wafer, when one of the plurality of pixel driving circuits is determined to be defective, there is a high possibility that other pixel driving circuits are also defective. For this reason, the reliability of the display apparatus may be deteriorated.

An embodiment of the present specification provides a display apparatus capable of improving reliability.

The objectives to be solved by the embodiments of the present disclosure are not limited to the objectives mentioned above, and other objectives not mentioned will be clearly understood by those skilled in the art from the following descriptions.

A display apparatus according to an aspect of the present specification includes a plurality of pixel driving circuits and at least one dummy pixel driving circuit disposed apart from each other on a substrate, a plurality of driving wires disposed corresponding to the plurality of pixel driving circuits, and a test wire electrically connected to the dummy pixel driving circuit.

A display apparatus according to another aspect of the present specification includes a plurality of pixel driving circuits and at least one dummy pixel driving circuit disposed apart from each other on a substrate, a plurality of driving wires disposed corresponding to the plurality of pixel driving circuits, and two wires electrically connected to one dummy pixel driving circuit, in which an end portion of each of the two wires is exposed.

A display apparatus according to still another aspect of the present specification includes a plurality of pixel driving circuits, and at least first dummy pixel driving circuit and at least one second dummy pixel driving circuit disposed apart from each other on a substrate, a plurality of driving wires disposed corresponding to the plurality of pixel driving circuits, and two lines connected to one first dummy pixel driving circuit. One line of the two lines connects the first dummy pixel driving circuit and the second dummy pixel driving circuit. An end portion of the other line of the two lines is exposed.

According to the present specification, by detecting defects in the pixel driving circuits, the reliability of the display apparatus may be improved.

According to the present specification, by minimizing or reducing the possibility that a plurality of pixel driving circuits are defective, it is possible to optimize the process of the display apparatus and minimize or reduce the possibility that the display apparatus is defective. Consequently, it is possible to reduce greenhouse gases from the viewpoint of producing the display apparatus.

The effects of the present disclosure are not limited to the effects mentioned above, and other effects not mentioned will be clearly understood by those skilled in the art to which the technical idea of the present disclosure pertains from the following description.

It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the disclosure and together with the description serve to explain the principles of the disclosure. In the drawings:

FIG. 1 is an exploded perspective view illustrating a display device according to an example embodiment of the present specification;

FIG. 2 is a plan view illustrating the display device according to an example embodiment of the present specification;

FIG. 3 is an enlarged view illustrating the display device according to an example embodiment of the present specification;

FIG. 4 is a diagram illustrating a circuit structure according to an example embodiment of the present specification;

FIG. 5 is a plan view illustrating the display device according to an example embodiment of the present specification;

FIG. 6 is a plan view illustrating the display device according to an example embodiment of the present specification;

FIG. 7 is a plan view illustrating the display device according to an example embodiment of the present specification;

FIGS. 8A and 8B are sectional views illustrating the display device according to an example embodiment of the present specification;

FIG. 9 is a sectional view illustrating the display device according to an example embodiment of the present specification;

FIG. 10 is a diagram illustrating a first electrode of the display device according to an example embodiment of the present specification;

FIG. 11 is a diagram illustrating a plurality of half-finished panels disposed on an example mother substrate;

FIG. 12 is a diagram illustrating an example embodiment of a disposition relationship between a half-finished panel and test pads on an example mother substrate;

FIG. 13 is a diagram illustrating a display panel separated from the example mother substrate;

FIG. 14 is a cross-sectional view of the display apparatus according to an example embodiment of the present specification;

FIG. 15 is a diagram illustrating resistance measurement of an example dummy pixel driving circuit;

FIG. 16 is a diagram illustrating example test pads separated by a cutting process;

FIG. 17 is a diagram illustrating another example embodiment of a disposition relationship between a half-finished panel and test pads on an example mother substrate;

FIG. 18 is a diagram illustrating a display apparatus according to another example embodiment of the present specification;

FIG. 19 is a diagram illustrating a protection layer that is disposed in the display panel according to the example embodiment;

FIG. 20 is a diagram illustrating another example embodiment of the display apparatus according to the example embodiment of the present specification;

FIG. 21 is a diagram illustrating another example embodiment of a disposition relationship between a half-finished panel and test pads on an example mother substrate;

FIG. 22 is a diagram illustrating another example embodiment of a disposition relationship between a half-finished panel and test pads on an example mother substrate;

FIG. 23 is a diagram illustrating resistance measurement of a first dummy pixel driving circuit and a second dummy pixel driving circuit;

FIG. 24 is a diagram illustrating another example embodiment of the display apparatus according to the example embodiment of the present specification;

FIG. 25 is a diagram illustrating another example embodiment of a disposition relationship between a half-finished panel and a test pad of a mother substrate;

FIG. 26 is a diagram illustrating another embodiment of a disposition relationship between a half-finished panel and a test pad of an example mother substrate; and

FIGS. 27 to 30 are diagrams illustrating apparatuses to which the display apparatuses according to example embodiments of the present specification can be applied.

### DETAILED DESCRIPTION

The advantages and features of the present disclosure and methods for accomplishing the same can be more clearly understood from various example embodiments described below with reference to the accompanying drawings. However, the present disclosure is not limited to the following embodiments but may be implemented in various different forms. Rather, the following example embodiments will make the disclosure of the present disclosure complete and allow those skilled in the art to completely comprehend the scope of the present disclosure. The protected scope of present disclosure may be defined by the scope of the accompanying claims and their equivalents.

Shapes, sizes, ratios, angles, numbers, and the like disclosed in the drawings for describing the embodiments of the present disclosure are examples, and the present disclosure is not limited to the illustrated items. Like reference numerals refer to like elements throughout. In addition, in describing the present disclosure, where the detailed description of the related known technology may unnecessarily obscure the subject matter of the present disclosure, the detailed description thereof may be omitted.

The terms such as “comprising”, “including”, “having” and “consisting of” used herein are generally intended to allow other components to be added unless the terms are used with a more limiting term like “only”. References to the singular shall be construed to include the plural unless expressly stated otherwise.

In interpreting a component, it is interpreted to include an error range even if there is no separate description.

In the case of a description of a positional relationship, for example, where the positional relationship of two parts is described as ‘on,’ ‘at an upper portion,’ ‘at a lower portion,’ ‘next to, and the like, one or more other parts may be located between the two parts unless a more limiting term like ‘immediately’ or ‘directly’ is used.

Where a temporal contextual relationship is described, such as “after,” “following,” “next to,” or “before,” it may also include non-contiguous cases unless a more limiting term like “immediately” or “directly” is used.

In the description for the embodiments, the first, second, etc., are used to describe various components, but these components are not limited by these terms. These terms are only used to refer to one component separately from another. Therefore, the first component mentioned below may be a second component, and vice versa, within the technical idea of the present disclosure.

Terms such as first, second, A, B, (a), (b), and the like may be used to describe elements of the embodiments of the present specification. Such terms are intended only to refer to one component separately from another and are not intended to define the nature, sequence, order, or number of such components.

Where a component is described as “connected,” “coupled,” or “attached” to another component, it is to be understood that the component may be directly connected or attached to the other component, but that there may also be other components “interposed” between the respective components which may be indirectly connected or attached where not specifically stated.

Where a component or layer is described as “contacting” or “overlapping” another component or layer, the component or layer may directly contact or overlap the other component or layer, but unless there is a specific statement, it should be understood that other components may be interposed between the components that are indirectly contacting or overlapping.

It should be understood that the term “at least one” includes all possible combinations of one or more related components. For example, the meaning of “at least one of the first, second, and third components” includes not only the first, second, or third component, but also any combination of two or more of the first, second, and third components.

The expression of a first element, a second elements, “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

“First direction,” “second direction,” “third direction,” “X-axis direction,” “Y-axis direction,” and “Z-axis direction” should not be interpreted only as geometric relationships that are perpendicular to each other, but may mean a broader directionality within the range that the configuration of the present specification may function.

The following example embodiments may be combined or associated with each other in whole or in part, and various types of interlocking and driving are technically possible. The embodiments may be implemented independently of each other or together in an interrelated relationship.

Any implementation described herein as an “example” is not necessarily to be construed as preferred or advantageous over other implementations.

Unless otherwise defined, all terms (including technical and scientific terms) used herein have the same meaning as commonly understood by one of ordinary skill in the art to which example embodiments belong. It should be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Advantages and features of the present disclosure and implementation methods thereof will be clarified through the following example embodiments described with reference to the accompanying drawings. The present disclosure may, however, be embodied in different forms and should not be construed as limited to the embodiments set forth herein. Rather, these example embodiments may be provided so that this disclosure may be sufficiently thorough and complete to assist those skilled in the art to fully understand the scope of the present disclosure.

Hereinafter, various example embodiments of the present disclosure will be described in detail with reference to the accompanying drawings.

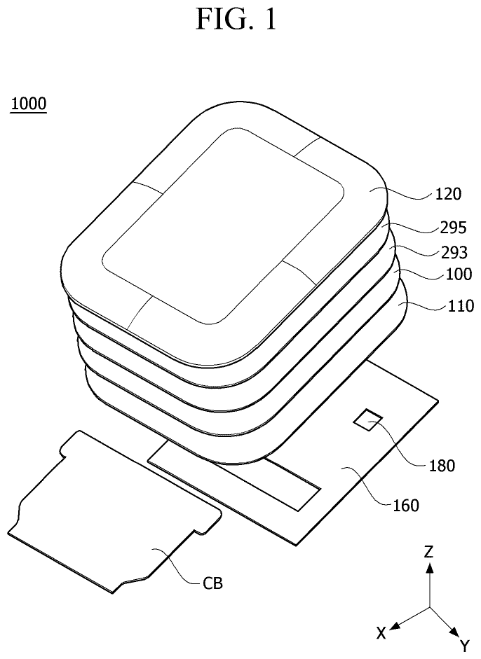

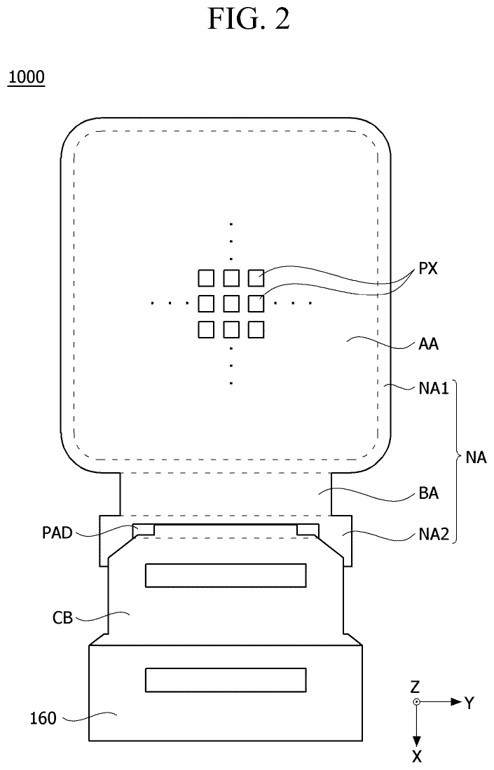

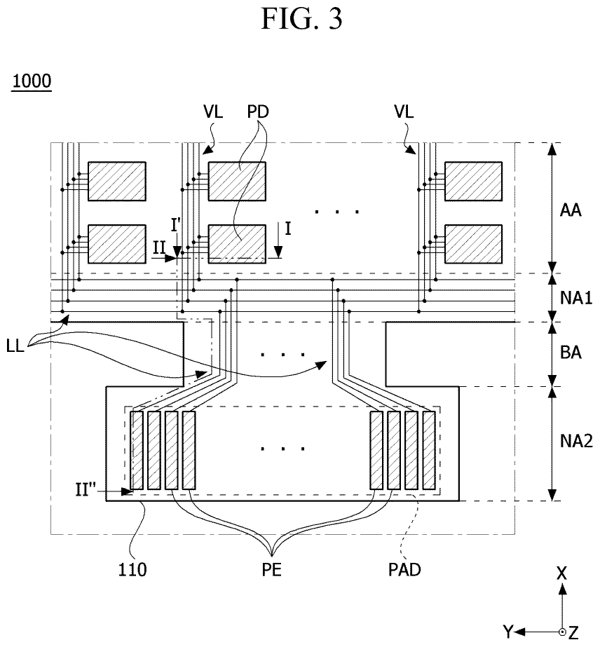

FIG. 1 is an exploded perspective view illustrating a display device according to an embodiment of the present specification. FIG. 2 is a plan view illustrating the display device according to an embodiment of the present specification. FIG. 3 is an enlarged view illustrating the display device according to an embodiment of the present specification.

As shown in FIGS. 1 to 3, the display device 1000 according to an embodiment of the present specification may include the display panel 100, a polarizing layer 293, an adhesive layer 295, a cover 120, a support substrate 110, a flexible circuit board CB, and a printed circuit board 160.

For example, the display device 1000 may include a substrate 110. The substrate 110 may be a component that supports other components of the display device 1000. The substrate 110 may be formed of an insulating material. The substrate 110 may be formed of glass, resin, or the like. Furthermore, the substrate 110 may be formed of a material having flexibility. For example, the substrate 110 may be formed of a plastic material having flexibility, such as polyimide (PI). However, embodiments of the present specification are not limited thereto.

The display panel 100 may implement the display of information, video, and/or images provided to a user. For example, the display panel 100 may include a display area AA and a non-display area NA. For example, the substrate 110 may include the display area AA and the non-display area NA. The display area AA and the non-display area NA are not limited to being described only with respect to the substrate 110 but may be described across the entire display device 1000.

The display area AA may be an area where an image is displayed. The display area AA may include a plurality of pixels PX. Each of the plurality of pixels PX may include a plurality of sub-pixels. A plurality of light emitting elements may be arranged in each of the plurality of sub-pixels. The configuration of the plurality of light emitting elements may vary depending on the type of the display device 1000. For example, in the case where the display device 1000 is an inorganic light emitting display, each of the light emitting elements may be a light-emitting diode (LED), a micro light-emitting diode (micro LED), or a mini light-emitting diode (mini LED); however, embodiments of the present specification are not limited thereto.

The non-display area NA may be an area where no image is displayed. Various wires, circuits, and the like for driving the plurality of pixels PX in the display area AA may be arranged in the non-display area NA. For example, various wires and a driving circuit may be formed in the non-display area NA, and a pad portion PAD, to which an integrated circuit, a printed circuit, and the like are connected, may be located in the non-display area NA; however, embodiments of the present specification are not limited thereto.

For example, the driving circuit may be a data driving circuit and/or a gate driving circuit; however, embodiments of the present specification are not limited thereto. Wires for supply of control signals provided to control the driving circuits may be arranged on the display panel 100. For instance, the control signals may include various timing signals, including a clock signal, an input data enable signal, and synchronization signals; however, embodiments of the present specification are not limited thereto. The control signals may be received through the pad portion PAD. For example, link wires LL for transmitting signals may be arranged in the non-display area NA. For instance, driving components such as the flexible circuit board CB and the printed circuit board 160 may be connected to the pad portion PAD.

According to the present specification, the non-display area NA may include a first non-display area NA1, a bending area BA, and a second non-display area NA2. For example, the first non-display area NA1 may be an area that encloses at least a portion of the display area AA. The bending area BA may be an area extending from at least one of a plurality of sides of the first non-display area NA1, and may be a bendable area. The second non-display area NA2 may be an area extending from the bending area BA. The pad portion PAD may be located in the second non-display area NA2. For example, the bending area BA may be in a bent state, and a remaining area of the substrate 110, other than the bending area BA, may be in a flat state. In this case, as the bending area BA bends, the second non-display area NA2 may be positioned over a rear surface of the display area AA. However, embodiments of the present specification are not limited thereto.

The display area AA of the substrate 110 or the display device 1000 may be formed in various shapes depending on the design of the display device 1000. For example, the display area AA may be formed in a rectangular shape with four rounded corners; however, embodiments of the present specification are not limited thereto. In another example, the display area AA may be formed in a rectangular shape with four right-angled corners or in a circular shape; however, embodiments of the present specification are not limited thereto.

According to the present specification, the width of the second non-display area NA2, in which a plurality of pad electrodes PE are arranged, may be greater than the width of the bending area BA, in which only a plurality of link wires LL are arranged. Furthermore, the width of the display area AA, in which a plurality of sub-pixels are arranged, may be greater than the width of the bending area BA, in which only the plurality of link wires LL are arranged. Although in the drawings the width of the bending area BA is illustrated as being smaller than that of other areas of the substrate 110, the shape of the substrate 110, including the bending area BA, is merely illustrative, and embodiments of the present specification are not limited thereto.

As shown in FIG. 3, a plurality of pixel driving circuits PD may be arranged in the display area AA. The plurality of pixel driving circuits PD may be circuits configured to drive the light-emitting elements of the plurality of sub-pixels. Each of the plurality of pixel driving circuits PD may include a plurality of transistors including a driving transistor, a storage capacitor, and the like, and may supply control signals, power, and drive current to the light-emitting elements of a plurality of corresponding sub-pixels to control emission operations of the light-emitting elements.

For example, each pixel driving circuit PD may include a power wire, and a signal wire provided to control the on/off state of emission and/or the emission time of the light-emitting elements. For instance, the plurality of pixel driving circuits PD may each be a driving driver fabricated on a semiconductor substrate through a metal-oxide-silicon field effect transistor (MOSFET) fabrication process, but embodiments of the present specification are not limited thereto. The driving driver may include a plurality of pixel driving circuits PD, and may drive a plurality of sub-pixels.

Referring also to FIG. 1, the flexible circuit board CB and the printed circuit board 160 may be located below the display panel 100. The flexible circuit board CB and the printed circuit board 160 may be located on at least one side edge of the display panel 100, but embodiments of the present specification are not limited thereto. One side of the flexible circuit board CB may be attached to the display panel 100, and another side thereof may be attached to the printed circuit board 160; however, embodiments of the present specification are not limited thereto. The flexible circuit board CB may be a flexible film, but embodiments of the present specification are not limited thereto.

The pad portion PAD including the plurality of pad electrodes PE is located in the second non-display area NA2. A driving component including at least one flexible circuit board (or flexible film) CB and the printed circuit board 160 may be attached or bonded to the pad portion PAD. The plurality of pad electrodes PE of the pad portion PAD may be electrically connected to the at least one flexible circuit board (or flexible film) CB, and may transmit various signals (or power) from the printed circuit board 160 and the flexible circuit board (or flexible film) CB to the plurality of pixel driving circuits PD in the display area AA.

The flexible circuit board (or flexible film) CB may be a film in which various components are arranged on a base film having flexibility. For example, a driving integrated circuit (IC), such as a gate driver IC or a data driver IC, may be arranged on the flexible circuit board (or flexible film) CB, but embodiments of the present specification are not limited thereto. The driving IC may be a component that processes data and driving signals for displaying an image. The driving IC may be arranged by a method, such as chip on glass (COG), chip on film (COF), or tape carrier package (TCP), depending on the mounting method; however, embodiments of the present specification are not limited thereto. The flexible circuit board (or flexible film) CB may be attached or bonded onto the plurality of pad electrodes PE through a conductive adhesive layer, but embodiments of the present specification are not limited thereto.

The printed circuit board 160 may be a component that is electrically connected to the at least one flexible circuit board (or flexible film) CB and configured to supply signals to the driving IC. The printed circuit board 160 may be located on one side of the flexible circuit board (or flexible film) CB, and may be electrically connected to the flexible circuit board (or flexible film) CB. Various types of components configured to supply different signals to the driving IC may be arranged on the printed circuit board 160. For example, various components, such as a timing controller, a power supply unit, a memory, a processor, or the like may be arranged on the printed circuit board 160. For instance, the printed circuit board 160 may include a power management integrated circuit (PMIC); however, embodiments of the present specification are not limited thereto.

The printed circuit board 160 may include at least one hole 180, but embodiments of the present specification are not limited thereto. An internal component configured to detect ambient light, temperature or the like, which can be provided to a plurality of sensors, may be located in an area corresponding to the at least one hole 180. For example, the internal component may include an ambient light sensor (ALS), a temperature sensor, or the like, but embodiments of the present specification are not limited thereto. For instance, the hole 180 may be a through-hole or the like; however, embodiments of the present specification are not limited thereto.

As shown in FIG. 1, the polarizing layer 293 may be located on the display panel 100. The polarizing layer 293 may prevent or reduce light generated from an external light source from entering the display panel 100 and affecting the light-emitting elements or the like.

The cover 120 may be located on the polarizing layer 293. The cover 120 may be a component provided to protect the display panel 100. The adhesive layer 295 may be located between the polarizing layer 293 and the cover 120. The cover 120 may be attached to the display panel 100 by the adhesive layer 295. The adhesive layer 295 may include an optically clear adhesive (OCA), an optically clear resin (OCR), a pressure sensitive adhesive (PSA), or the like, but embodiments of the present specification are not limited thereto.

The support substrate 110 may be located between the display panel 100 and the printed circuit board 160. The support substrate 110 may reinforce the rigidity of the display panel 100. The support substrate 110 may be a backplate, however, embodiments of the present specification are not limited thereto.

As shown in FIGS. 1 to 3, a plurality of link wires LL may be arranged in the non-display area NA. The plurality of link wires LL may be wires that transmit various signals from the at least one flexible circuit board (or a flexible film) CB and the printed circuit board 160 to the display area AA. The plurality of link wires LL may extend from a plurality of pad electrodes PE in the second non-display area NA2 toward the bending area BA and the first non-display area NA1, and may be electrically connected to a plurality of driving wires VL in the display area AA. The plurality of pixel driving circuits PD may be driven in response to signals received from the at least one flexible circuit board (or flexible film) CB and the printed circuit board 160 through the driving wires VL in the display area AA and the link wires LL in the non-display area NA.

For example, the plurality of driving wires VL, along with a plurality of link wires LL, may be wires provided to transmit signals output from the flexible circuit board (or flexible film) CB and the printed circuit board 160 to the plurality of pixel driving circuits PD. The plurality of driving wires VL may be arranged in the display area AA and may be electrically connected to each of the plurality of pixel driving circuits PD. The plurality of driving wires VL may extend from the display area AA toward the non-display area NA, and may be electrically connected to the plurality of link wires LL. Accordingly, signals output from the flexible circuit board (or flexible film) CB and the printed circuit board 160 may be transmitted to each of the plurality of pixel driving circuits PD through the plurality of link wires LL and the plurality of driving wires VL.

As the bending area BA is bent, portions of the plurality of link wires LL may also be bent. Stress may be concentrated on the bent portions of the link wires LL, which may cause cracks in the link wires LL. Therefore, the plurality of link wires LL may be formed of a conductive material with excellent flexibility to reduce cracks during the bending of the bending area BA. For example, the plurality of link wires LL may be formed of a highly flexible conductive material such as gold (Au), silver (Ag), or aluminum (Al), but embodiments of the present specification are not limited thereto. Furthermore, the plurality of link wires LL may be formed of one of various conductive materials used in the display area AA. For example, the plurality of link wires LL may be formed of molybdenum (Mo), chromium (Cr), titanium (Ti), nickel (Ni), neodymium (Nd), copper (Cu), an alloy of silver (Ag) and magnesium (Mg), or other alloys thereof, but embodiments of the present specification are not limited thereto. The plurality of link wires LL may also be formed in a multilayer structure that includes various conductive materials. For example, a plurality of link wires LL may be formed in a triple-layer structure including titanium (Ti)/aluminum (Al)/titanium (Ti), but embodiments of the present specification are not limited thereto.

The plurality of link wires LL may be configured in various shapes to reduce stress. At least a portion of the plurality of link wires LL that is located in the bending area BA may extend in the same direction as the extension direction of the bending area BA, or may extend in a direction different from the extension direction of the bending area BA to reduce stress. For example, in the case where the bending area BA extends in one direction from the first non-display area NA1 toward the second non-display area NA2, at least a portion of the link wires LL that is located in the bending area BA may extend in a direction inclined relative to the one direction. In another example, at least a portion of the plurality of link wires LL may be configured in patterns of various shapes. For instance, at least a portion of the plurality of link wires LL that is located in the bending area BA may have a shape in which a conductive pattern, having at least one of a diamond shape, a rhombus shape, a trapezoidal wave shape, a triangular wave shape, a sawtooth wave shape, a sine wave shape, a circular shape, or an omega (Ω) shape, is repeatedly arranged; however, embodiments of the present specification are not limited thereto. Therefore, to minimize or reduce stress concentrated on the plurality of link wires LL and the resulting cracks, the plurality of link wires LL may have various shapes, including the aforementioned shapes; however, embodiments of the present specification are not limited thereto.

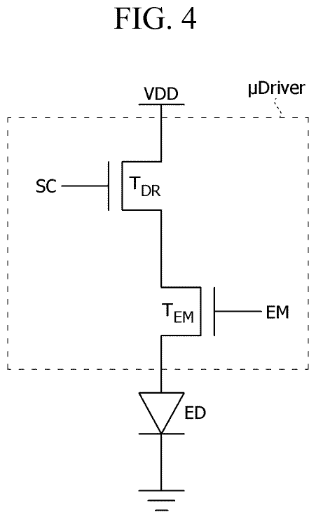

FIG. 4 is a diagram illustrating a circuit structure according to an embodiment of the present specification.

In FIG. 4, an example is illustrated in which a single light-emitting element ED is connected to a micro driver μDriver, but embodiments of the present specification are not limited thereto. For example, eight light-emitting elements ED may be connected to the single micro driver μDriver. In another example, sixteen light-emitting elements ED may be connected to the single micro driver μDriver, or thirty-two or sixty-four light-emitting elements ED may be simultaneously connected to the single micro driver μDriver. The light-emitting element ED may be a micro light-emitting element (μLED).

The single micro driver (μDriver) may include a driving transistor T_{DR} and a light-emitting transistor T_{EM}, but embodiments of the present specification are not limited thereto.

For example, the driving transistor T_{DR} may include a first electrode configured to receive a high-potential power supply voltage VDD, a second electrode connected to a first electrode of the light-emitting transistor T_{EM}, and a gate electrode configured to receive a scan signal SC. The scan signal SC that is applied to the gate electrode of the driving transistor T_{DR} may be a direct current (DC) voltage, and a fixed reference voltage Vref may be applied in each frame; however, embodiments of the present specification are not limited thereto.

The light-emitting transistor T_{EM} may include the first electrode connected to the second electrode of the driving transistor T_{DR}, a second electrode connected to the light-emitting element ED, and a gate electrode configured to receive an emission signal EM. The emission signal EM that is applied to the gate electrode of the light-emitting transistor T_{EM} may be a pulse width modulation (PWM) signal that varies in each frame; however, embodiments of the present specification are not limited thereto.

A first electrode of the light-emitting element ED may be connected to the second electrode of the light-emitting transistor T_{EM}, and a second electrode of the light-emitting element ED may be connected to ground. For example, the first electrode of the light-emitting element ED may be an anode electrode, and the second electrode of the light-emitting element ED may be a cathode electrode; however, embodiments of the present specification are not limited thereto.

The driving transistor T_{DR} and the light-emitting transistor T_{EM} may each be an n-type transistor or a p-type transistor.

In the micro driver μDriver, the driving transistor T_{DR} may be turned on in response to the scan signal SC applied from a timing controller T-CON, and the light-emitting transistor T_{EM} may be turned on in response to the emission signal EM. Accordingly, a drive current may be applied to the light-emitting element ED via the driving transistor T_{DR} and the light-emitting transistor T_{EM} due to the high-potential power supply voltage VDD applied to the first electrode of the driving transistor T_{DR}, thereby allowing the light-emitting element ED to emit light.

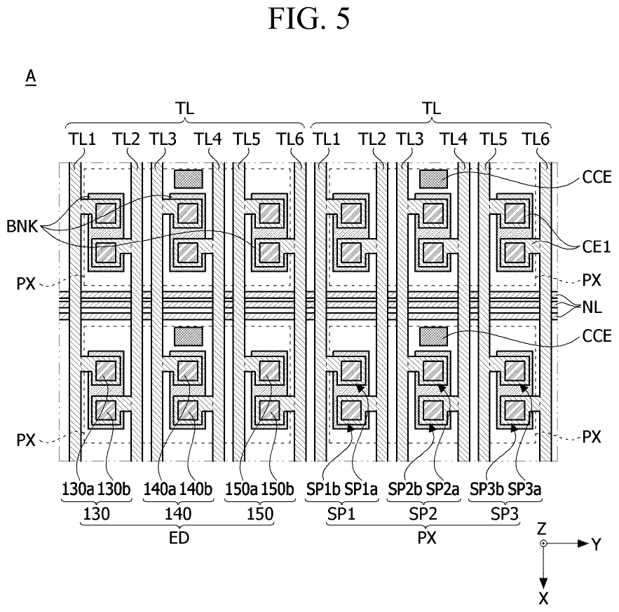

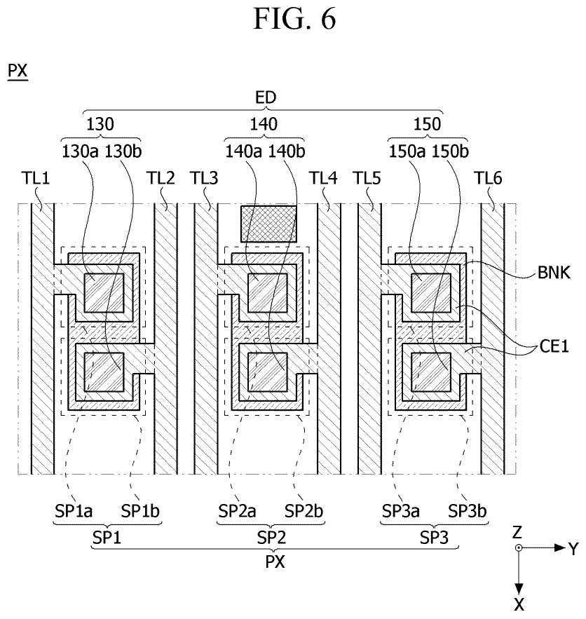

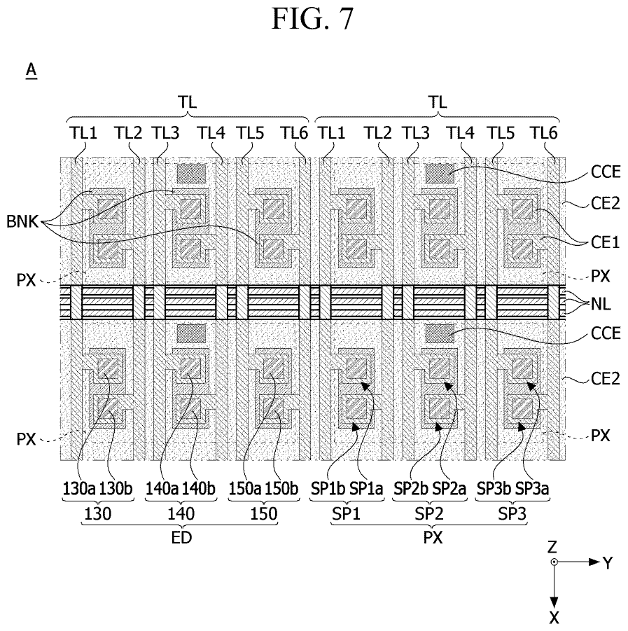

FIGS. 5 to 7 are plan views of the display device according to an embodiment of the present specification. For example, FIG. 5 is an enlarged plan view of a display area in which a plurality of pixels are included. For example, FIG. 6 is an enlarged plan view of a display area in which a single pixel is included. For instance, FIG. 7 is an enlarged plan view of a display area in which a plurality of pixels are included. In FIGS. 5 and 6, only a plurality of signal wires TL, a plurality of communication wires NL, a plurality of first electrodes CE1, a plurality of banks BNK, and a plurality of light-emitting elements ED are illustrated; however, embodiments of the present specification are not limited thereto. FIG. 7 is an enlarged plan view illustrating a plurality of second electrodes CE2 additionally arranged in FIG. 5.

As shown in FIGS. 5 and 6, a plurality of pixels PX, each formed of a plurality of sub-pixels, may be arranged in the display area AA. Each of the plurality of sub-pixels may include a light-emitting element ED, and may independently emit light. The plurality of sub-pixels may be arranged in a matrix form including a plurality of rows and a plurality of columns; however, embodiments of the present specification are not limited thereto.

The plurality of sub-pixels may include a first sub-pixel SP1, a second sub-pixel SP2, and a third sub-pixel SP3. For example, any one of the first sub-pixel SP1, the second sub-pixel SP2, or the third sub-pixel SP3 may be a red sub-pixel, another may be a green sub-pixel, and a remaining one may be a blue sub-pixel. The types of the plurality of sub-pixels are illustrative, and embodiments of the present specification are not limited thereto.

Each of the plurality of pixels PX may include at least one first sub-pixel SP1, at least one second sub-pixel SP2, and at least one third sub-pixel SP3. For example, each pixel PX may include a pair of first sub-pixels SP1, a pair of second sub-pixels SP2, and a pair of third sub-pixels SP3. The pair of first sub-pixels SP1 may include a first-first sub-pixel SP1a and a first-second sub-pixel SP1b. The pair of second sub-pixels SP2 may include a second-first sub-pixel SP2a and a second-second sub-pixel SP2b. The pair of third sub-pixels SP3 may include a third-first sub-pixel SP3a and a third-second sub-pixel SP3b. For example, each pixel PX may include the first-first sub-pixel SP1a and the first-second sub-pixel SP1b, the second-first sub-pixel SP2a and the second-second sub-pixel SP2b, and the third-first sub-pixel SP3a and the third-second sub-pixel SP3b; however, embodiments of the present specification are not limited thereto.

The plurality of sub-pixels that form each pixel PX may be arranged in various ways. For example, in each pixel PX, a pair of first sub-pixels SP1 may be arranged in the same column, a pair of second sub-pixels SP2 may be arranged in the same column, and a pair of third sub-pixels SP3 may be arranged in the same column. The first sub-pixels SP1, the second sub-pixels SP2, and the third sub-pixels SP3 may be arranged in the same row. The number and arrangement of the plurality of sub-pixels that form each pixel PX are illustrative, and embodiments of the present specification are not limited thereto.

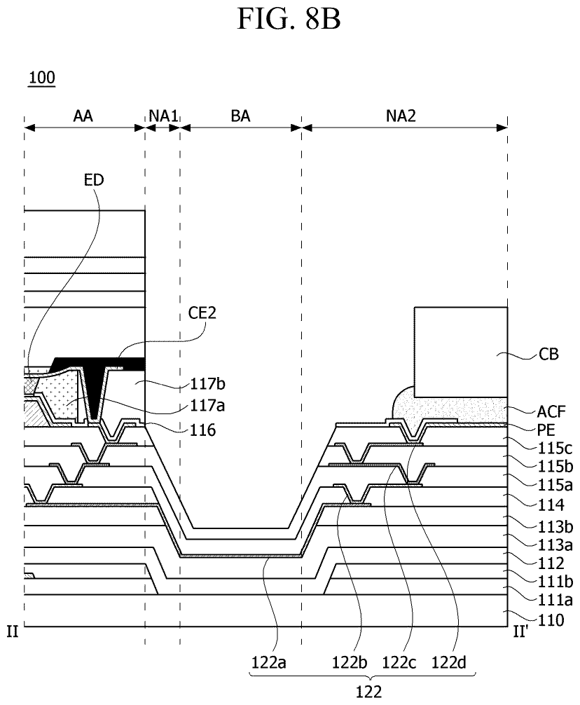

A plurality of signal wires TL may be arranged in an area between the plurality of sub-pixels. The plurality of signal wires TL may extend in a column direction between the plurality of sub-pixels. The plurality of signal wires TL may be wires that transmit an anode voltage from the pixel driving circuit PD to the plurality of sub-pixels. For example, the plurality of signal wires TL may be electrically connected to a plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal wires TL. For example, the first electrodes CE1 may be electrodes electrically connected to anode electrodes 134 (shown in FIG. 9) of the light-emitting elements ED. Accordingly, the anode voltage from the signal wires TL may be transmitted to the anode electrodes 134 of the light-emitting elements ED through the first electrodes CE1.

Accordingly, the structure of the display device 1000 may be simplified by using the pixel driving circuit PD in which a plurality of pixel circuits are integrated, instead of forming a plurality of transistors and storage capacitors in each of the plurality of sub-pixels. Furthermore, as the circuits respectively arranged in the plurality of sub-pixels are integrated into a single pixel driving circuit PD, high-efficiency and low-power operation may be achieved.

The plurality of signal wires TL may include a first signal wire TL1, a second signal wire TL2, a third signal wire TL3, a fourth signal wire TL4, a fifth signal wire TL5, and a sixth signal wire TL6. The first signal wire TL1 and the second signal wire TL2 may be respectively and electrically connected to the pair of first sub-pixels SP1. The third signal wire TL3 and the fourth signal wire TL4 may be respectively and electrically connected to the pair of second sub-pixels SP2. The fifth signal wire TL5 and the sixth signal wire TL6 may be respectively and electrically connected to the pair of third sub-pixels SP3.

The first signal wire TL1 may be located on one side of the pair of first sub-pixels SP1, and the second signal wire TL2 may be located on another side of the pair of first sub-pixels SP1. The first signal wire TL1 may be electrically connected to the first electrode CE1 of one of the pair of first sub-pixels SP1, for example, the first electrode CE1 of the first-first sub-pixel SP1a. The second signal wire TL2 may be electrically connected to the first electrode CE1 of a remaining one of the pair of first sub-pixels SP1, for example, the first electrode CE1 of the first-second sub-pixel SP1b.

The third signal wire TL3 may be located on one side of the pair of second sub-pixels SP2, and the fourth signal wire TL4 may be located on another side of the pair of second sub-pixels SP2. For example, the third signal wire TL3 may be located adjacent to the second signal wire TL2. The third signal wire TL3 may be electrically connected to the first electrode CE1 of one of the pair of second sub-pixels SP2, for example, the first electrode CE1 of the second-first sub-pixel SP2a. The fourth signal wire TL4 may be electrically connected to the first electrode CE1 of a remaining one of the pair of second sub-pixels SP2, for example, the first electrode CE1 of the second-second sub-pixel SP2b.

The fifth signal wire TL5 may be located on one side of the pair of third sub-pixels SP3, and the sixth signal wire TL6 may be located on another side of the pair of third sub-pixels SP3. For example, the fifth signal wire TL5 may be located adjacent to the fourth signal wire TL4. The sixth signal wire TL6 may be located adjacent to the first signal wire TL1 that is connected to an adjacent pixel PX. The fifth signal wire TL5 may be electrically connected to the first electrode CE1 of one of the pair of third sub-pixels SP3, for example, the first electrode CE1 of the third-first sub-pixel SP3a. The sixth signal wire TL6 may be electrically connected to the first electrode CE1 of a remaining one of the pair of third sub-pixels SP3, for example, the first electrode CE1 of the third-second sub-pixel SP3b.

The plurality of signal wires TL may be formed of a conductive material. For example, the plurality of signal wires TL may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO); however, embodiments of the present specification are not limited thereto. In another example, the plurality of signal wires TL may have a multilayer structure of conductive materials. For example, the plurality of signal wires TL may have a multilayer structure including titanium (Ti)/aluminum (Al)/titanium (Ti)/indium tin oxide (ITO); however, embodiments of the present specification are not limited thereto.

A plurality of communication wires NL may be arranged in an area between the plurality of pixels PX. The plurality of communication wires NL may be arranged to extend in a row direction in the area between the plurality of pixels PX. The plurality of communication wires NL may be arranged in an area between the plurality of second electrodes CE2, and may not overlap the plurality of second electrodes CE2. For example, the plurality of communication wires NL may be wires used for short-range communication such as near field communication (NFC). The plurality of communication wires NL may function as an antenna. For example, the plurality of communication wires NL may be a plurality of connection wires or the like; however, embodiments of the present specification are not limited thereto.

According to the present specification, a bank BNK may be located in each of the plurality of sub-pixels. The plurality of banks BNK may be structures on which the plurality of light-emitting elements ED are seated. The plurality of banks BNK may guide the positions of the plurality of light-emitting elements ED during a transfer process of transferring the plurality of light-emitting elements ED to the display device 1000. During the transfer process of the plurality of light-emitting elements ED, the plurality of light-emitting elements ED may be transferred onto the plurality of banks BNK. The plurality of banks BNK may be a bank pattern, structure, or the like, but embodiments of the present specification are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated. Accordingly, the banks BNK of the first sub-pixel SP1, the second sub-pixel SP2, and the third sub-pixel SP3, onto which different types of light-emitting elements ED are transferred, may be easily identified.

The bank BNK of the first-first sub-pixel SP1a and the bank BNK of the first-second sub-pixel SP1b may be connected to each other, or may be formed to be spaced apart or separated. For example, in view of design factors such as transfer process requirements or the like, the bank BNK of the first-first sub-pixel SP1a and the bank BNK of the first-second sub-pixel SP1b, on which light-emitting elements ED of the same type are arranged, may be connected to each other, or may be spaced apart or separated. The bank BNK of the second-first sub-pixel SP2a and the bank BNK of the second-second sub-pixel SP2b may be connected to each other, or may be formed to be spaced apart or separated. The bank BNK of the third-first sub-pixel SP3a and the bank BNK of the third-second sub-pixel SP3b may be connected to each other, or may be formed to be spaced apart or separated. Accordingly, the banks BNK of the pair of first sub-pixels SP1, the banks BNK of the pair of second sub-pixels SP2, and the banks BNK of the pair of third sub-pixels SP3 may be formed in various ways, and embodiments of the present specification are not limited thereto.

For instance, the plurality of banks BNK may be formed of an organic insulating material. The plurality of banks BNK may be configured as a single-layer or multilayer structure using an organic insulating material. For example, the plurality of banks BNK may be formed of photoresist, polyimide (PI), an acrylic-based material, or the like, but embodiments of the present specification are not limited thereto.

The first electrode CE1 may be located in each of the plurality of sub-pixels. The first electrode CE1 may be located on the bank BNK. The first electrode CE1 may be electrically connected to one of the plurality of signal wires TL. At least a portion of the first electrode CE1 may extend outward from the bank BNK, and may be electrically connected to the signal wire TL that is closest to the first electrode CE1. For example, a portion of the first electrode CE1 of the first-first sub-pixel SP1a may extend to one side area of the first-first sub-pixel SP1a, and may be electrically connected to the first signal wire TL1. A portion of the first electrode CE1 of the first-second sub-pixel SP1b may extend to another side area of the first-second sub-pixel SP1b, and may be electrically connected to the second signal wire TL2. A portion of the first electrode CE1 of the second-first sub-pixel SP2a may extend to one side area of the second-first sub-pixel SP2a, and may be electrically connected to the third signal wire TL3. A portion of the first electrode CE1 of the second-second sub-pixel SP2b may extend to another side area of the second-second sub-pixel SP2b, and may be electrically connected to the fourth signal wire TL4. A portion of the first electrode CE1 of the third-first sub-pixel SP3a may extend to one side area of the third-first sub-pixel SP3a, and may be electrically connected to the fifth signal wire TL5. A portion of the first electrode CE1 of the third-second sub-pixel SP3b may extend to another side area of the third-second sub-pixel SP3b, and may be electrically connected to the sixth signal wire TL6.

The first electrode CE1 may be electrically connected to the anode electrode 134 of the light-emitting element ED, and may transmit an anode voltage from the pixel driving circuit PD to the light-emitting element ED through the signal wire TL. Different voltages may be applied to the first electrode CE1 of each of the plurality of sub-pixels depending on an image that is displayed. For example, different voltages may be applied to the respective first electrodes CE1 of the plurality of sub-pixels. Hence, each first electrode CE1 may serve as a pixel electrode; however, embodiments of the present specification are not limited thereto.

The first electrode CE1 may be formed of a conductive material. For example, the first electrode CE1 may be integrally formed with the plurality of signal wires TL. For instance, the first electrode CE1 may be formed of the same conductive material as the plurality of signal wires TL; however, embodiments of the present specification are not limited thereto. For instance, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but embodiments of the present specification are not limited thereto. In another example, the first electrode CE1 may be formed as a multilayer structure using conductive materials. For instance, the plurality of first electrodes CE1 may be configured as a multilayer structure including titanium (Ti)/aluminum (Al)/titanium (Ti)/indium tin oxide (ITO); however, embodiments of the present specification are not limited thereto.

The light-emitting element ED may be located in each of the plurality of sub-pixels. The plurality of light-emitting elements ED may each be either an LED or a micro LED; however, embodiments of the present specification are not limited thereto. The plurality of light-emitting elements ED may be arranged on the banks BNK and the first electrodes CE1. The plurality of light-emitting elements ED may be arranged on the first electrodes CE1, and may be electrically connected to the first electrodes CE1. Accordingly, each of the light-emitting elements ED may receive an anode voltage from the corresponding pixel driving circuit PD through the corresponding signal wire TL and the associated first electrode CE1, thereby emitting light.

The plurality of light-emitting elements ED may include a first light-emitting element 130, a second light-emitting element 140, and a third light-emitting element 150. The first light-emitting element 130 may be located in the first sub-pixel SP1. The second light-emitting element 140 may be located in the second sub-pixel SP2. The third light-emitting element 150 may be located in the third sub-pixel SP3. For example, any one of the first light-emitting element 130, the second light-emitting element 140, or the third light-emitting element 150 may be a red light-emitting element, another may be a green light-emitting element, and a remaining one may be a blue light-emitting element; however, embodiments of the present specification are not limited thereto. Accordingly, various colors of light, including white, may be implemented by combining the red light, green light, and blue light emitted from the plurality of light-emitting elements ED. The types of the plurality of light-emitting elements ED are illustrative, and embodiments of the present specification are not limited thereto.

The first light-emitting element 130 may include a first-first light-emitting element 130a located in the first-first sub-pixel SP1a, and a first-second light-emitting element 130b located in the first-second sub-pixel SP1b. The second light-emitting element 140 may include a second-first light-emitting element 140a located in the second-first sub-pixel SP2a, and a second-second light-emitting element 140b located in the second-second sub-pixel SP2b. The third light-emitting element 150 may include a third-first light-emitting element 150a located in the third-first sub-pixel SP3a, and a third-second light-emitting element 150b located in the third-second sub-pixel SP3b.

As shown in FIGS. 5, 6, and 7 together, the second electrode CE2 may be located in each of the plurality of sub-pixels. The second electrodes CE2 may be located on the corresponding light-emitting elements ED. The second electrodes CE2 may be electrically connected to the corresponding pixel driving circuits PD through a plurality of contact electrodes CCE.

For example, each second electrode CE2 may be electrically connected to a cathode electrode 135 (shown in FIG. 9) of the corresponding light-emitting element ED, and may transmit a cathode voltage from the pixel driving circuit PD to the light-emitting element ED. The same cathode voltage may be applied to the second electrode CE2 of each of the plurality of sub-pixels. For instance, the same voltage may be applied to the second electrode CE2 of each of the plurality of sub-pixels and the cathode electrode 135 of the light-emitting element ED. Accordingly, the second electrode CE2 may serve as a common electrode; however, embodiments of the present specification are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, at least some of the sub-pixels may share the second electrode CE2. For example, the second electrodes CE2 of at least some of the plurality of pixels PX that are arranged in the same row may be connected to each other. For instance, a single second electrode CE2 may be located for a plurality of pixels PX. A single second electrode CE2 may be arranged for every n sub-pixels.

For example, some of the respective second electrodes CE2 of the plurality of sub-pixels may be spaced apart or arranged separately from each other. For instance, the second electrode CE2 connected to the pixels PX that are in an nth row and the second electrode CE2 connected to the pixels PX that are in an (n+1)th row may be spaced apart or arranged separately from each other. For example, the plurality of second electrodes CE2 may be spaced apart from each other with a plurality of communication wires NL interposed therebetween and extending in a row direction. Accordingly, the number of the plurality of sub-pixels may be greater than the number of the plurality of second electrodes CE2. In another example, all of the second electrodes CE2 of the plurality of sub-pixels may be connected to each other such that only one second electrode CE2 is located on the substrate 110, and embodiments of the present specification are not limited thereto.

The plurality of second electrodes CE2 may be formed of a transparent conductive material; however, embodiments of the present specification are not limited thereto. The plurality of second electrodes CE2 may be made of a transparent conductive material, thus allowing light emitted from the light-emitting elements ED to be directed upward above the second electrodes CE2. For example, the second electrodes CE2 may be formed of a transparent conductive material such as indium tin oxide (ITO), indium zinc oxide (IZO), indium gallium zinc oxide (IGZO), or the like; however, embodiments of the present specification are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For instance, one second electrode CE2 may overlap a plurality of contact electrodes CCE.

For example, the plurality of contact electrodes CCE may be electrically connected to the plurality of second electrodes CE2. The plurality of contact electrodes CCE may be arranged between the substrate 110 and the plurality of second electrodes CE2, and may transmit a cathode voltage from the pixel driving circuits PD to the second electrodes CE2.

For example, in the case where a micro LED (or an inorganic light-emitting element) is used as the light-emitting element ED, the display device 1000 may be fabricated by forming a plurality of micro LEDs on a wafer and transferring the micro LEDs to the substrate 110 of the display device 1000. During the process of transferring the plurality of light-emitting elements ED, each having a micro-size, from the wafer to the substrate 110, various defects may occur. For instance, in some sub-pixels, a non-transfer defect may occur in which the light-emitting element ED is not successfully transferred. In other sub-pixels, a misalignment defect may occur in which the light-emitting element ED is transferred out of an intended position thereof due to alignment errors. Furthermore, even if the transfer process is normally performed, the transferred light-emitting element ED itself may be defective. Accordingly, in view of potential defects that may occur during the transfer process of the plurality of light-emitting elements ED, a plurality of light-emitting elements ED of the same type may be transferred to each sub-pixel. A lighting inspection may be performed on the plurality of light-emitting elements ED, and ultimately, only the one light-emitting element ED that is determined to be normal may be used.

For example, both the first-first light-emitting element 130a and the first-second light-emitting element 130b may be transferred together onto a single pixel PX, and presence of defects thereof may be inspected. If both the first-first light-emitting element 130a and the first-second light-emitting element 130b are determined to be normal, only the first-first light-emitting element 130a may be used, while the first-second light-emitting element 130b may remain unused. In another example, if only the first-second light-emitting element 130b, among the first-first light-emitting element 130a and the first-second light-emitting element 130b, is determined to be normal, the first-first light-emitting element 130a may remain unused, and only the first-second light-emitting element 130b may be used. Accordingly, even if a plurality of light-emitting elements ED of the same type are transferred onto each pixel PX, ultimately, only one light-emitting element ED may be used.

Accordingly, any one of the pair of light-emitting elements ED may be a main (or primary) light-emitting element ED, and a remaining light-emitting element ED may be a redundancy light-emitting element ED. The redundancy light-emitting element ED may be an additional light-emitting element ED transferred as a backup in case of failure of the main light-emitting element ED. If the main light-emitting element ED is defective, the redundancy light-emitting element ED may be used as a replacement. Therefore, transferring the main and redundancy light-emitting elements ED together onto a single pixel PX may minimize or reduce the degradation in the display quality due to the defects occurring in the main light-emitting element ED and the redundancy light-emitting element ED.

For example, the first-first light-emitting element 130a, the second-first light-emitting element 140a, and the third-first light-emitting element 150a transferred onto each pixel PX may be used as main light-emitting elements ED. The first-second light-emitting element 130b, the second-second light-emitting element 140b, and the third-second light-emitting element 150b may be used as redundancy light-emitting elements ED.

The display panel 100 according to the present specification includes the first electrode CE1 located below the light-emitting element ED. The light output efficiency may be improved by exposing a portion of a conductive layer with relatively high reflectance among a plurality of conductive layers arranged in the first electrode CE1 through a process such as an etching process. However, during the process of fabricating the display panel 100, the exposed conductive layer of the first electrode CE1 may be exposed to solutions used in various processes, which may cause corrosion or damage to the exposed conductive layer. For example, aluminum included in the first electrode CE1 may be easily corroded when exposed to a solution such as tetramethylammonium hydroxide (TMAH).

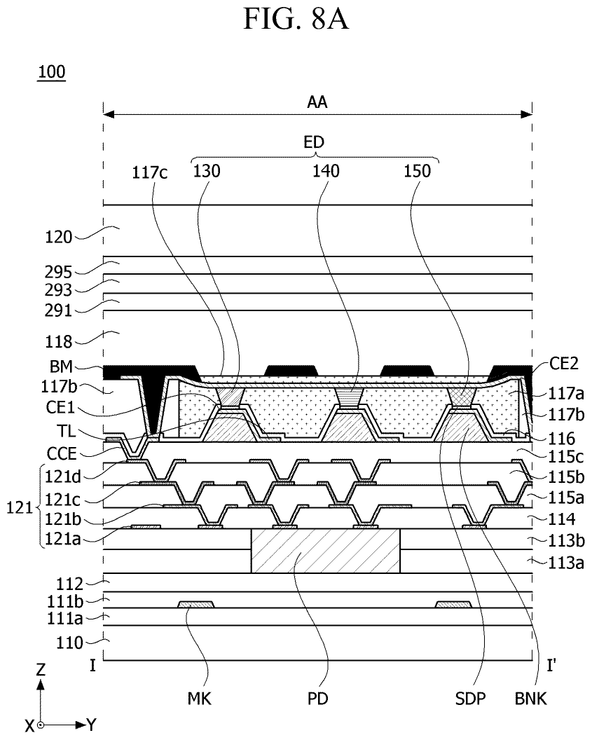

FIG. 8A and FIG. 8B are a sectional view illustrating the display device according to an embodiment of the present specification. For example, FIG. 8A and FIG. 8B are sectional views illustrating the display area AA, the first non-display area NA1, the bending area BA, and the second non-display area NA2, taken along line I-I′ of FIG. 3.

As shown in FIG. 8A and FIG. 8B, a first buffer layer 111a and a second buffer layer 111b may be arranged in a remaining area of the substrate 110 except for the bending area BA.

The first buffer layer 111a and the second buffer layer 111b may be located in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be formed of an inorganic insulating material. For example, the first buffer layer 111a and the second buffer layer 111b may be configured as a single-layer or multilayer structure formed of silicon oxide (SiOx) or silicon nitride (SiNx); however, embodiments of the present specification are not limited thereto.

For example, a portion of the first buffer layer 111a and a portion of the second buffer layer 111b in the bending area BA may be removed. An upper surface of the substrate 110 located in the bending area BA may be exposed from the first buffer layer 111a and the second buffer layer 111b. Cracks that may occur in the first buffer layer 111a and the second buffer layer 111b during bending may be minimized or reduced by removing the first buffer layer 111a and the second buffer layer 111b, which are formed of an inorganic insulating material, from the bending area BA.

A plurality of alignment keys MK may be arranged between the first buffer layer 111a and the second buffer layer 111b. The plurality of alignment keys MK may be configured to identify the position of the pixel driving circuit PD during the process of fabricating the display device 1000. For example, the plurality of alignment keys MK may be configured to align the position of the pixel driving circuit PD, which is transferred onto an adhesive layer 112. In another example, the plurality of alignment keys MK may be omitted.

The adhesive layer 112 may be located on the second buffer layer 111b. The adhesive layer 112 may be located in the display area AA, the first non-display area NA1, the bending area BA, and the second non-display area NA2. In another example, at least a portion of the adhesive layer 112 in the non-display area NA, including the bending area BA, may be removed. For example, the adhesive layer 112 may be formed of any one of an adhesive polymer, epoxy resin, UV-curable resin, a polyimide-based material, an acrylate-based material, a urethane-based material, or polydimethylsiloxane (PDMS); however, embodiments of the present specification are not limited thereto.

In the display area AA, the pixel driving circuit PD may be located on the adhesive layer 112. In the case where the pixel driving circuit PD is implemented as a driving driver, the driving driver may be mounted on the adhesive layer 112 through a transfer process; however, embodiments of the present specification are not limited thereto.

A first protective layer 113a and a second protective layer 113b may be arranged on the adhesive layer 112 and the pixel driving circuit PD. The first protective layer 113a and the second protective layer 113b may be arranged to enclose side surfaces of the pixel driving circuit PD; however, embodiments of the present specification are not limited thereto. For example, the second protective layer 113b may be located to cover at least a portion of an upper surface of the pixel driving circuit PD. For example, at least one of the first protective layer 113a or the second protective layer 113b located in the bending area BA may be omitted. For instance, the first protective layer 113a may be provided throughout the display area AA and the non-display area NA, and the second protective layer 113b may be partially provided in the display area AA, the first non-display area NA1, and the second non-display area NA2. For example, a portion of the second protective layer 113b in the bending area BA may be removed; however, embodiments of the present specification are not limited thereto.

The first protective layer 113a and the second protective layer 113b may be formed of an organic insulating material; however, embodiments of the present specification are not limited thereto. For example, the first protective layer 113a and the second protective layer 113b may be formed of photoresist, polyimide (PI), a photoacrylic-based material, or the like; however, embodiments of the present specification are not limited thereto. For instance, the first protective layer 113a and the second protective layer 113b may each be an overcoating layer or an insulating layer; however, embodiments of the present specification are not limited thereto.

According to the present specification, a plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected to the plurality of signal wires TL and the plurality of contact electrodes CCE through the plurality of first connection wires 121. For instance, the plurality of first connection wires 121 may include a first-first connection wire 121a, a first-second connection wire 121b, a first-third connection wire 121c, and a first-fourth connection wire 121d; however, embodiments of the present specification are not limited thereto.

For example, the plurality of first-first connection wires 121a may be arranged on the second protective layer 113b. The plurality of first-first connection wires 121a may be electrically connected to the pixel driving circuit PD. The plurality of first-first connection wires 121a may transmit a voltage output from the pixel driving circuit PD to the first electrode CE1 or the second electrode CE2.

For instance, a third protective layer 114 may be located on the second protective layer 113b. The third protective layer 114 may be provided throughout the display area AA and the non-display area NA. In the bending area BA, the third protective layer 114 may cover or enclose a side surface of the second protective layer 113b and an upper surface of the first protective layer 113a. The third protective layer 114 may be formed of an organic insulating material. For example, the third protective layer 114 may be formed of photoresist, polyimide (PI), a photoacrylic-based material, or the like; however, embodiments of the present specification are not limited thereto. For example, the first protective layer 113a, the second protective layer 113b, and the third protective layer 114 may be formed of the same material; however, embodiments of the present specification are not limited thereto. For example, the first protective layer 113a, the second protective layer 113b, and the third protective layer 114 may each be an insulating layer; however, embodiments of the present specification are not limited thereto.

A plurality of first-second connection wires 121b may be arranged on the third protective layer 114. The plurality of first-second connection wires 121b may be connected to or directly connected to the pixel driving circuit PD. For example, some of the plurality of first-second connection wires 121b may be directly connected to the pixel driving circuit PD through a contact hole of the third protective layer 114. Some others of the first-second connection wires 121b may be electrically connected to the first-first connection wire 121a through a contact hole of the third protective layer 114. However, embodiments of the present specification are not limited thereto. A voltage output from the pixel driving circuit PD may be transmitted to the first electrode CE1 or the second electrode CE2 through the plurality of first-second connection wires 121b and other connection wires.

A first insulating layer 115a may be located on a plurality of first-second connection wires 121b. The first insulating layer 115a may be provided throughout the display area AA and the non-display area NA; however, embodiments of the present specification are not limited thereto. The first insulating layer 115a may be formed of an organic insulating material; however, embodiments of the present specification are not limited thereto. For example, the first insulating layer 115a may be formed of photoresist, polyimide (PI), a photoacrylic-based material, or the like; however, embodiments of the present specification are not limited thereto.

A plurality of first-third connection wires 121c may be arranged on the first insulating layer 115a. The plurality of first-third connection wires 121c may be electrically connected to the plurality of first-second connection wires 121b. For example, the first-third connection wires 121c may be electrically connected to the first-second connection wires 121b through a contact hole of the first insulating layer 115a.

A second insulating layer 115b may be located on the plurality of first-third connection wires 121c. The second insulating layer 115b may be provided in a remaining area except for the bending area BA; however, embodiments of the present specification are not limited thereto. The second insulating layer 115b may be located in the display area AA, the first non-display area NA1, and the second non-display area NA2; however, embodiments of the present specification are not limited thereto. For example, a portion of the second insulating layer 115b that is located in the bending area BA may be removed. The second insulating layer 115b may be formed of an organic insulating material; however, embodiments of the present specification are not limited thereto. For example, the second insulating layer 115b may be formed of photoresist, polyimide (PI), a photoacrylic-based material, or the like; however, embodiments of the present specification are not limited thereto.

A plurality of first-fourth connection wires 121d may be arranged on the second insulating layer 115b. The plurality of first-fourth connection wires 121d may be electrically connected to the plurality of first-third connection wires 121c. For example, the first-fourth connection wires 121d may be electrically connected to the first-third connection wires 121c through a contact hole of the second insulating layer 115b.

According to the present specification, a plurality of second connection wires 122 may be arranged on the second protective layer 113b in the non-display area NA. The plurality of second connection wires 122 may be wires provided to transmit, to the pixel driving circuit PD in the display area AA, signals that are transmitted from the flexible circuit board (or flexible film) CB and the printed circuit board 160 (see FIG. 1) to the pad portion PAD. For example, the plurality of second connection wires 122 may be electrically connected to the plurality of pad electrodes PE, and may receive signals from the flexible circuit board (or flexible film) CB and the printed circuit board.

For example, the plurality of second connection wires 122 may extend from the pad portion PAD toward the display area AA and transmit signals to the wires in the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d.

A plurality of second-first connection wires 122a may be arranged on the second protective layer 113b. The plurality of second-first connection wires 122a may extend from the second non-display area NA2 to the bending area BA and the first non-display area NA1. The plurality of second-first connection wires 122a may transmit, to the pixel driving circuit PD in the display area AA, signals that are transmitted from the flexible circuit board (or flexible film) CB and the printed circuit board to the pad portion PAD.

A plurality of second-second connection wires 122b may be arranged on the third protective layer 114. The plurality of second-second connection wires 122b may be arranged in the second non-display area NA2. The second-second connection wires 122b may be electrically connected to the second-first connection wires 122a through a contact hole of the third protective layer 114. Accordingly, signals from the flexible circuit board (or flexible film) CB and the printed circuit board may be transmitted to the second-first connection wires 122a through the second-second connection wires 122b.

A plurality of second-third connection wires 122c may be arranged on the first insulating layer 115a. The second-third connection wires 122c may be located in the second non-display area NA2. The second-third connection wires 122c may be electrically connected to the second-second connection wires 122b through a contact hole of the first insulating layer 115a. Accordingly, signals from the flexible circuit board (or flexible film) CB and the printed circuit board may be transmitted to the second-first connection wires 122a through the second-third connection wires 122c and the second-second connection wires 122b.

A plurality of second-fourth connection wires 122d may be arranged on the second insulating layer 115b. The second-fourth connection wires 122d may be located in the second non-display area NA2. The second-fourth connection wires 122d may be electrically connected to the second-third connection wires 122c through a contact hole of the second insulating layer 115b. Accordingly, signals from the flexible film FF and the printed circuit board may be transmitted to the second-first connection wires 122a through the second-fourth connection wires 122d, the second-third connection wires 122c, and the second-second connection wires 122b.

The plurality of first connection wires 121 and the plurality of second connection wires 122 may be formed of either a highly flexible conductive material or any one of various conductive materials applicable to the display area AA. For example, the second connection wires 122, a portion of which is located in the bending area BA, may be formed of a highly flexible conductive material such as gold (Au), silver (Ag), aluminum (Al), or the like; however, embodiments of the present specification are not limited thereto. In another example, the plurality of first connection wires 121 and the plurality of second connection wires 122 may be formed of molybdenum (Mo), chromium (Cr), titanium (Ti), nickel (Ni), neodymium (Nd), copper (Cu), an alloy of silver (Ag) and magnesium (Mg), or other alloys thereof. However, embodiments of the present specification are not limited thereto.

A third insulating layer 115c may be located on the plurality of first connection wires 121 and the plurality of second connection wires 122. The third insulating layer 115c may be located in a remaining area except for the bending area BA; however, embodiments of the present specification are not limited thereto. The third insulating layer 115c may be located in the display area AA, the first non-display area NA1, and the second non-display area NA2. A portion of the third insulating layer 115c in the bending area BA may be removed. The third insulating layer 115c may be formed of an organic insulating material, but embodiments of the present specification are not limited thereto. For example, the third insulating layer 115c may be formed of photoresist, polyimide (PI), a photoacrylic-based material, or the like; however, embodiments of the present specification are not limited thereto.

In the display area AA, the plurality of banks BNK may be arranged on the third insulating layer 115c. The plurality of banks BNK may be arranged to respectively overlap the plurality of sub-pixels. One or more light-emitting elements ED of the same type may be located over each of the plurality of banks BNK.

In the display area AA, the plurality of signal wires TL may be arranged on the third insulating layer 115c. The plurality of signal wires TL may be located in areas between the plurality of banks BNK. For example, the plurality of signal wires TL may be located adjacent to any one of the plurality of banks BNK.

In the display area AA, the plurality of contact electrodes CCE may be arranged on the third insulating layer 115c. The plurality of contact electrodes CCE may each supply a cathode voltage from the pixel driving circuit PD to the corresponding second electrode CE2.

The first electrodes CE1 may each be located on the corresponding bank BNK. For example, the first electrode CE1 may be provided to extend from an adjacent signal wire TL toward an upper portion of the bank BNK. The first electrode CE1 may be formed on both an upper surface and a side surface of the bank BNK. For example, the first electrode CE1 may be provided to extend from the signal wire TL on an upper surface of the third insulating layer 115c to the side surface and the upper surface of the bank BNK.

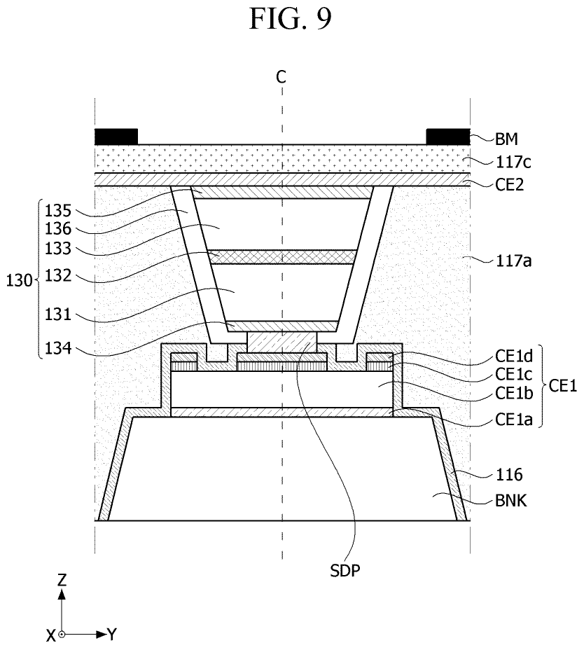

FIG. 9 is a sectional view illustrating the display device according to an embodiment of the present specification. FIG. 9 is a sectional view illustrating a sub-pixel including a light-emitting element located in the display area AA. FIG. 10 is a diagram illustrating the first electrode of the display device according to an embodiment of the present specification.

As shown in FIGS. 9 and 10, the first electrode CE1 may be configured with a plurality of conductive layers. For example, the first electrode CE1 may include a first conductive layer CE1a, a second conductive layer CE1b, a third conductive layer CE1c, and a fourth conductive layer CE1d. However, embodiments of the present specification are not limited thereto.

The first conductive layer CE1a may be located on the bank BNK. The second conductive layer CE1b may be located on the first conductive layer CE1a. The third conductive layer CE1c may be located on the second conductive layer CE1b. The fourth conductive layer CE1d may be located on the third conductive layer CE1c. For example, each of the first conductive layer CE1a, the second conductive layer CE1b, the third conductive layer CE1c, and the fourth conductive layer CE1d may be formed of at least one of titanium (Ti), molybdenum (Mo), aluminum (Al), or indium tin oxide (ITO). However, embodiments of the present specification are not limited thereto.

According to the present specification, some conductive layers with high reflection efficiency among the plurality of conductive layers forming the first electrode CE1 may be configured as alignment keys and/or reflectors for aligning the light-emitting element ED. For example, the second conductive layer CE1b among the plurality of conductive layers of the first electrode CE1 may include a reflective material. For instance, the second conductive layer CE1b may include aluminum (Al), but embodiments of the present specification are not limited thereto. Accordingly, the second conductive layer CE1b may be configured as a reflector. Furthermore, the high reflection efficiency of the second conductive layer CE1b may facilitate identification thereof in the manufacturing process. Hence, the position or transfer position of the light-emitting element ED may be aligned based on the second conductive layer CE1b.

For example, to configure the second conductive layer CE1b as a reflector, the third conductive layer CE1c and the fourth conductive layer CE1d that cover the second conductive layer CE1b may be partially removed or etched. For instance, the upper surface of the second conductive layer CE1b may be exposed by removing or etching a portion of the third conductive layer CE1c and a portion of the fourth conductive layer CE1d located on the bank BNK. For example, except for central portions where a solder pattern SDP is located and perimeter portions (or edge portions) of the third conductive layer CE1c and the fourth conductive layer CE1d, remaining portions may be removed. For instance, the perimeter portion (or edge portion) of each of the third conductive layer CE1c, which is formed of titanium (Ti), and the fourth conductive layer CE1d, which is formed of indium tin oxide (ITO), may remain unetched. Accordingly, in a mask process for forming the first electrode CE1, other conductive layers such as the second conductive layer CE1b of the first electrode CE1 may be protected from corrosion caused by a tetramethylammonium hydroxide (TMAH) solution used in the mask process.

According to the present specification, the first conductive layer CE1a and the third conductive layer CE1c may each include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has excellent adhesion to a solder pattern SDP and exhibits corrosion resistance and acid resistance. However, embodiments of the present specification are not limited thereto.

The first conductive layer CE1a, the second conductive layer CE1b, the third conductive layer CE1c, and the fourth conductive layer CE1d may be sequentially deposited and patterned through a photolithography process and an etching process. However, embodiments of the present specification are not limited thereto.

As shown in FIG. 10, the first electrode CE1 may include the first conductive layer CE1a, the second conductive layer CE1b located on the first conductive layer CE1a, the third conductive layer CE1c located on the second conductive layer CE1b, and the fourth conductive layer CE1d located on the third conductive layer CE1c. The second conductive layer CE1b may be formed of a material having a higher light reflectance than the third conductive layer CE1c and the fourth conductive layer CE1d. For example, the second conductive layer CE1b may include aluminum (Al) or silver (Ag). Accordingly, in the display panel 100 according to the present specification, the second conductive layer CE1b, which has a higher light reflectance than the fourth conductive layer CE1d that is in contact with the solder pattern SDP, may be exposed, thereby improving the light output efficiency of the light-emitting element ED by reflecting light emitted from the light-emitting element ED using the second conductive layer CE1b.

The first electrode CE1 may include a groove G. For example, the first electrode CE1 may include the groove G formed in an upper surface of the first electrode CE1. For example, the first electrode CE1 may include the groove G that is formed as a concave shape in the upper surface of the first electrode CE1. The groove G may be formed along the perimeter of the first electrode CE1, and may be arranged to be spaced apart from an edge of the upper surface of the first electrode CE1. The groove G may be formed in the upper surface of the first electrode CE1 through a photolithography process and an etching process; however, embodiments of the present specification are not limited thereto.

A portion of the upper surface of the second conductive layer CE1b may be exposed by the groove G, and the exposed portion of the second conductive layer CE1b may reflect light, which is emitted by the light-emitting element ED and incident on the second conductive layer CE1b through the groove G, thereby improving the light output efficiency of the display device 1000.

As the groove G is formed, the first electrode CE1 may include a first electrode area A1 that is in contact with the solder pattern SDP, a second electrode area A2 located outside the first electrode area A1, and a third electrode area A3 located outside the second electrode area A2. The second electrode area A2 may be an area of the second conductive layer CE1b on which the third conductive layer CE1c and the fourth conductive layer CE1d are not located. The second electrode area A2 may serve as a reflective area in which the incident light onto the second conductive layer CE1b through the groove G are reflected to improve the light output efficiency of the light-emitting element ED.

Although in FIG. 10 the first electrode CE1 is illustrated as including the first electrode area CE1A1, the second electrode area CELA2, and the third electrode area CE1A3, embodiments of the present specification are not limited thereto. For example, to improve the light output efficiency of the display panel 100, the third electrode area CE1A3 may be omitted. For instance, the first electrode CE1 may include only the first electrode area CE1A1 and the second electrode area CE1A2.

The first electrode CE1 may be formed to have a preset thickness T. Since the first electrode CE1 may be formed using a plurality of conductive layers with different resistances, even though the design specifications for the resistance of the first electrode CE1 change, the resistance of the first electrode CE1 may be adjusted by controlling the thicknesses of the conductive layers. Here, the thickness of each conductive layer may refer to a width between its opposing surfaces, measured along the Z-axis direction.

The first conductive layer CE1a may be formed to have a first thickness CT1. The first thickness CT1 may be adjustable. The first conductive layer CE1a may have a lower light reflectance and a higher resistance than the second conductive layer CE1b. For example, the first conductive layer CE1a may include titanium (Ti) or molybdenum (Mo); however, embodiments of the present specification are not limited thereto.

The second conductive layer CE1b may be formed to have a second thickness T2 greater than the first thickness T1. The second conductive layer CE1b may be formed of a material with a higher light reflectance than the third conductive layer CE1c and the fourth conductive layer CE1d. For example, the second conductive layer CE1b may include aluminum (Al) or silver (Ag); however, the embodiments of the present specification are not limited thereto.

The third conductive layer CE1c may be formed to have a third thickness CT3. The third thickness CT3 may be adjustable. The third conductive layer CE1c may be formed of a material with a lower light reflectance and a higher resistance than the second conductive layer CE1b. For example, the third conductive layer CE1c may include titanium (Ti) or molybdenum (Mo); however, embodiments of the present specification are not limited thereto.

The fourth conductive layer CE1d may be formed to have a fourth thickness CT4. The fourth thickness CT4 may be adjustable. The fourth conductive layer CE1d may be formed of a material with a lower light reflectance than the second conductive layer CE1b. For example, the fourth conductive layer CE1d may include a transparent conductive oxide, such as indium tin oxide (ITO) or indium zinc oxide (IZO), which has excellent adhesion to the solder pattern SDP and exhibits corrosion resistance and acid resistance. However, embodiments of the present specification are not limited thereto.

The thicknesses of the third conductive layer CE1c and the fourth conductive layer CE1d may be determined, taking into account the reflection efficiency depending on the depth of the groove G. Even when the first electrode CE1 is configured to have a preset thickness T, the display panel 100 according to the present specification may achieve the desired resistance of the first electrode CE1 by adjusting the thicknesses of the first conductive layer CE1a and the second conductive layer CE1b.

According to the present specification, the signal wire TL, the contact electrode CCE, and the pad electrode PE that are arranged in the same layer as the first electrode CE1 may be configured as a multilayer structure formed of a conductive material. However, embodiments of the present specification are not limited thereto. For example, the signal wire TL, the contact electrode CCE, and the pad electrode PE may be formed as a multilayer structure including indium tin oxide (ITO)/titanium (Ti)/aluminum (Al)/titanium (Ti). However, embodiments of the present specification are not limited thereto.

According to the present specification, the solder pattern SDP may be located on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP; however, embodiments of the present specification are not limited thereto. For example, the first electrode CE1 and the anode electrode 134 of the light-emitting element ED may be electrically connected through cutectic bonding using the solder pattern SDP; however, embodiments of the present specification are not limited thereto. For instance, in the case where the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. Through cutectic bonding, the light-emitting element ED may be bonded to the solder pattern SDP and the first electrode CE1 without the need for additional adhesive material. For example, the solder pattern SDP may be formed of indium (In), tin (Sn), or an alloy thereof; however, embodiments of the present specification are not limited thereto. For instance, the solder pattern SDP may be a pattern, a pattern layer, a bonding pad, or a junction pad, but embodiments of the present specification are not limited thereto.

According to the present specification, a passivation layer 116 may be located on the plurality of signal wires TL, the plurality of first electrodes CE1, the plurality of contact electrodes CCE, and the third insulating layer 115c. For example, the passivation layer 116 may be located in the display area AA, the first non-display area NA1, and the second non-display area NA2. A portion of the passivation layer 116 that is located in the bending area BA may be removed. A portion of the passivation layer 116 that covers the plurality of pad electrodes PE in the second non-display area NA2 may also be removed. Because the passivation layer 116 is located to cover areas other than areas where the bending area BA, the plurality of pad electrodes PE and the solder pattern SDP are located, the penetration of moisture or impurities into the light-emitting element ED may be reduced. For example, the passivation layer 116 may be configured as a single-layer or multilayer structure including silicon oxide (SiOx) or silicon nitride (SiNx); however, embodiments of the present specification are not limited thereto. For instance, the passivation layer 116 may function as a protective layer or an insulating layer, but embodiments of the present specification are not limited thereto. For example, the passivation layer 116 may include a hole through which the solder pattern SDP is exposed.

The passivation layer 116 may be located to cover the groove G of the first electrode CE1, thereby protecting the exposed second conductive layer CE1b. For example, to form the solder pattern SDP, an organic insulating material, which may be used as a mask, may be deposited on the passivation layer 116. Thereafter, a groove corresponding to the formation position of the solder pattern SDP may be formed in the organic insulating material by performing an exposure process and an etching process of removing, using an etching solution, a portion of the organic insulating material that has reacted to the exposure process. Subsequently, a material for forming the solder pattern SDP may be placed inside the groove, thereby forming the solder pattern SDP on the first electrode CE1. The organic insulating material used as the mask may then be removed through a mask removal process. If the position at which the organic insulating material is exposed deviates from a preset position, an upper portion of the second conductive layer CE1b exposed to a developing solution used in the exposure process may become exposed, causing damage to the second conductive layer CE1b. However, in the display panel 100 according to the present specification, the passivation layer 116 may prevent or reduce such damage to the second conductive layer CE1b in advance. Accordingly, in the display panel 100 according to the present specification, the passivation layer 116 may enhance the reliability of the manufacturing process.

The passivation layer 116, extending inward from the upper edge of the first electrode CE1 may be arranged to cover the groove G to protect the exposed second conductive layer CE1b. An end portion of the passivation layer 116 extending inward on the top surface of the first electrode CE1 may overlap with an edge of the first electrode area A1 in the Z-axis direction. Here, “inward” may refer to a direction toward the center (C) of the first electrode CE1, and “outward” may refer to the opposite direction of inward. The center (C) of the first electrode CE1 may be the center of a horizontal plane of the first electrode CE1 extending in the X-axis direction and the Y-axis direction. And, the end portion of the passivation layer 116, extending inward on the top surface of the first electrode CE1, may be the inner end portion of the passivation layer 116.

In each of the plurality of sub-pixels, the light-emitting element ED may be located on the solder pattern SDP. A first light-emitting element 130 may be located in a first sub-pixel SP1. A second light-emitting element 140 may be located in a second sub-pixel SP2. A third light-emitting element 150 may be located in a third sub-pixel SP3.

The light-emitting element ED may be formed on a silicon wafer by a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like. However, embodiments of the present specification are not limited thereto.

As shown in FIG. 9, the first light-emitting element 130 may include an anode electrode 134, a first semiconductor layer 131, an active layer 132, a second semiconductor layer 133, a cathode electrode 135, and an encapsulation film 136. However, embodiments of the present specification are not limited thereto. For example, the first light-emitting element 130 may not include the encapsulation film 136.

The first semiconductor layer 131 may be located on the solder pattern SDP. The second semiconductor layer 133 may be located on the first semiconductor layer 131.

For example, either the first semiconductor layer 131 or the second semiconductor layer 133 may be implemented with a compound semiconductor such as a III-V group or II-VI group semiconductor, or the like, and may be doped with an impurity (or dopant). For instance, either the first semiconductor layer 131 or the second semiconductor layer 133 may be an n-type doped semiconductor layer, and the other may be a p-type doped semiconductor layer. However, embodiments of the present specification are not limited thereto. For example, at least one of the first semiconductor layer 131 or the second semiconductor layer 133 may be a layer formed by doping a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), with an n-type or p-type impurity. However, embodiments of the present specification are not limited thereto. For example, the n-type impurity may include silicon (Si), germanium (Ge), selenium (Se), carbon (C), tellurium (Te), or tin (Sn); however, embodiments of the present specification are not limited thereto. For example, the p-type impurity may include magnesium (Mg), zinc (Zn), calcium (Ca), strontium (Sr), barium (Ba), beryllium (Be), or the like, but embodiments of the present specification are not limited thereto.

For example, the first semiconductor layer 131 and the second semiconductor layer 133 may be respectively formed of a nitride semiconductor including an n-type impurity and a nitride semiconductor including a p-type impurity. However, embodiments of the present specification are not limited thereto. For instance, the first semiconductor layer 131 may be a nitride semiconductor including a p-type impurity, and the second semiconductor layer 133 may be a nitride semiconductor including an n-type impurity; however, embodiments of the present specification are not limited thereto.

The active layer 132 may be located between the first semiconductor layer 131 and the second semiconductor layer 133. The active layer 132 may receive holes and electrons from the first semiconductor layer 131 and the second semiconductor layer 133 and emit light. For example, the active layer 132 may be formed in one of a single well structure, a multiple well structure, a single quantum well structure, a multi-quantum well (MQW) structure, a quantum dot structure, or a quantum wire structure. However, embodiments of the present specification are not limited thereto. For instance, the active layer 132 may be formed of indium gallium nitride (InGaN), gallium nitride (GaN), or the like; however, embodiments of the present specification are not limited thereto.

In another example, the active layer 132 may include a multi-quantum well (MQW) structure having a well layer and a barrier layer with a higher band gap than the well layer. For instance, the active layer 132 may be configured with a well layer formed of InGaN and a barrier layer formed of AlGaN. However, embodiments of the present specification are not limited thereto.

The anode electrode 134 may be located between the first semiconductor layer 131 and the solder pattern SDP. For example, the anode electrode 134 may electrically connect the first semiconductor layer 131 and the first electrode CE1. An anode voltage output from the pixel driving circuit PD may be applied to the first semiconductor layer 131 through the signal wire TL, the first electrode CE1, and the anode electrode 134. For instance, the anode electrode 134 may be formed of a conductive material capable of eutectic bonding with the solder pattern SDP; however, embodiments of the present specification are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, embodiments of the present specification are not limited thereto.

The cathode electrode 135 may be located on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material to allow light emitted from the light-emitting element ED to pass upward above the light-emitting element ED. However, embodiments of the present specification are not limited thereto. For instance, the cathode electrode 135 may be formed of a material such as indium tin oxide (ITO), indium zinc oxide (IZO), indium gallium zinc oxide (IGZO), or the like; however, embodiments of the present specification are not limited thereto.

The encapsulation film 136 may be located on at least a portion of the first semiconductor layer 131, the active layer 132, the second semiconductor layer 133, the anode electrode 134, and the cathode electrode 135. For example, the encapsulation film 136 may enclose at least a portion of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For instance, the encapsulation film 136 may be located on a side surface of the first semiconductor layer 131, a side surface of the active layer 132, and a side surface of the second semiconductor layer 133.

For example, the encapsulation film 136 may be located on at least a portion of the anode electrode 134 and the cathode electrode 135, e.g., an edge portion (or peripheral portion or one side) of the anode electrode 134 and an edge portion (or peripheral portion or one side) of the cathode electrode 135. At least a portion of the anode electrode 134 may be exposed from the encapsulation film 136, allowing the anode electrode 134 to be connected to the solder pattern SDP. For instance, at least a portion of the cathode electrode 135 may be exposed from the encapsulation film 136, allowing the cathode electrode 135 to be connected to the second electrode CE2. For example, the encapsulation film 136 may be formed of an insulating material such as silicon nitride (SiNx) or silicon oxide (SiOx); however, embodiments of the present specification are not limited thereto.

In another example, the encapsulation film 136 may have a structure in which a reflective material is dispersed in a resin layer. However, embodiments of the present specification are not limited thereto. For example, the encapsulation film 136 may be formed as a reflector with various structures; however, embodiments of the present specification are not limited thereto. The encapsulation film 136 may reflect light, which is emitted from the active layer 132, upward, thereby improving light extraction efficiency. For instance, the encapsulation film 136 may be a reflective layer; however, embodiments of the present specification are not limited thereto.

According to the present specification, although the light-emitting element ED has been described with a vertical structure, embodiments of the present specification are not limited thereto. For example, the light-emitting element ED may have a lateral structure or a flip-chip structure. The light-emitting element ED may be an inorganic light-emitting element, but embodiments of the present specification are not limited thereto.

Although the first light-emitting element 130 has been described with reference to FIG. 9, the second light-emitting element 140 and the third light-emitting element 150 may have substantially the same structure as the first light-emitting element 130. For example, the second light-emitting element 140 and the third light-emitting element 150 may have substantially the same components as the first light-emitting element 130, including the first semiconductor layer 131, the active layer 132, the second semiconductor layer 133, the anode electrode 134, the cathode electrode 135, and the encapsulation film 136.

According to the present specification, a first optical layer 117a may be located around the plurality of light-emitting elements ED in the display area AA. The first optical layer 117a may enclose the plurality of light-emitting elements ED. For example, the first optical layer 117a may be formed to cover the plurality of light-emitting elements ED and the banks BNK in the respective areas of the plurality of sub-pixels. For instance, the first optical layer 117a may cover the banks BNK, a portion of the passivation layer 116, and spaces between the plurality of light-emitting elements ED. The first optical layer 117a may be located between or cover the spaces between the plurality of light-emitting elements ED included in each pixel PX and the spaces between the plurality of banks BNK. For instance, the first optical layer 117a may extend in a first direction (X-axis direction) and have spacing in a second direction (Y-axis direction). For example, the first optical layer 117a may be formed to enclose the side surfaces of the light-emitting elements ED and the banks BNK between the passivation layer 116 and the second electrode CE2; however, embodiments of the present specification are not limited thereto. For instance, the first optical layer 117a may be a diffusion layer or a sidewall diffusion layer, but embodiments of the present specification are not limited thereto.

The first optical layer 117a may include an organic insulating material in which fine particles are dispersed. However, embodiments of the present specification are not limited thereto. For example, the first optical layer 117a may be formed of siloxane in which fine metal particles, such as titanium dioxide (TiO₂) particles, are dispersed, but embodiments of the present specification are not limited thereto. Light emitted from the plurality of light-emitting elements ED may be scattered by the fine particles dispersed in the first optical layer 117a and then emitted to the outside of the display device 1000. Accordingly, the first optical layer 117a may enhance the extraction efficiency of the light emitted from the plurality of light-emitting elements ED.

For example, the first optical layer 117a may be located in each of the plurality of pixels PX, or may be located in some pixels PX that are arranged in the same row. However, embodiments of the present specification are not limited thereto. For example, the first optical layer 117a may be provided in each of the plurality of pixels PX, or the plurality of pixels PX may share a single first optical layer 117a. In another example, each of the plurality of sub-pixels may separately include the first optical layer 117a, but embodiments of the present specification are not limited thereto.

According to the present specification, a second optical layer 117b may be located on the passivation layer 116 in the display area AA. For example, the second optical layer 117b may be located around the first optical layer 117a. For example, the second optical layer 117b may be formed to enclose the first optical layer 117a. For instance, the second optical layer 117b may be in contact with a side surface of the first optical layer 117a. For example, the second optical layer 117b may be located in an area between the plurality of pixels PX; however, embodiments of the present specification are not limited thereto. For example, the second optical layer 117b may be a diffusion layer, a diffusion layer window, a window diffusion layer, or the like, but embodiments of the present specification are not limited thereto.

The second optical layer 117b may be formed of an organic insulating material; however, embodiments of the present specification are not limited thereto. The second optical layer 117b may be formed of the same material as the first optical layer 117a; however, embodiments of the present specification are not limited thereto. For example, the first optical layer 117a may include fine particles, and the second optical layer 117b may not include fine particles. For example, the second optical layer 117b may be formed of siloxane; however, embodiments of the present specification are not limited thereto.

For example, the thickness of the first optical layer 117a may be smaller than that of the second optical layer 117b, but embodiments of the present specification are not limited thereto. Accordingly, in a plan view, the area where the first optical layer 117a is located may include a concave portion that is recessed inward relative to an upper surface of the second optical layer 117b.

According to the present specification, the second electrode CE2 may be located on the first optical layer 117a and the second optical layer 117b. For example, the second electrode CE2 may be electrically connected to the plurality of contact electrodes CCE through a contact hole of the second optical layer 117b. For example, the second electrode CE2 may be located on the plurality of light-emitting elements ED. For instance, the second electrode CE2 may include a transparent conductive oxide such as indium tin oxide (ITO) or indium zinc oxide (IZO); however, embodiments of the present specification are not limited thereto. For example, the second electrode CE2 may be located in contact with the cathode electrode 135. For instance, the second electrode CE2 may overlap the first optical layer 117a. For example, the second electrode CE2 may cover an outer planar surface of the first optical layer 117a.

The second electrode CE2 may extend continuously in the first direction (X-axis direction) of the substrate 110. Accordingly, the second electrode CE2 may be connected in common to the plurality of pixels PX that are arranged in the first direction (X-axis direction) of the substrate 110. For example, the second electrode CE2 may be connected in common to the plurality of pixels PX.

According to the present specification, the second electrode CE2 may extend continuously on the first optical layer 117a, the second optical layer 117b, and the light-emitting element ED. The area where the first optical layer 117a is located may include a concave portion that is recessed inward relative to the upper surface of the second optical layer 117b. Accordingly, a first portion of the second electrode CE2 located on the first optical layer 117a may be provided along the concave portion and, therefore, may be positioned lower than a second portion of the second electrode CE2 located on the second optical layer 117b.

A third optical layer 117c may be located on the second electrode CE2. The third optical layer 117c may be located to overlap the plurality of light-emitting elements ED and the first optical layer 117a. Since the third optical layer 117c is located on the second electrode CE2 and the plurality of light-emitting elements ED, mura may be prevented or reduced from occurring in some of the plurality of light-emitting elements ED. For example, when the plurality of light-emitting elements ED are transferred onto the substrate 110 of the display device 1000, process deviations or other factors may result in non-uniform spacing between the plurality of light-emitting elements ED. If the spacing between the plurality of light-emitting elements ED is non-uniform, respective light output areas of the plurality of light-emitting elements ED may be arranged non-uniformly, making mura visible to a user. In view of the aforementioned issue, the third optical layer 117c may be configured to uniformly diffuse light over the plurality of light-emitting elements ED, thereby reducing the perception of mura caused by light emission from some light-emitting elements ED. Therefore, the third optical layer 117c enables light emitted from the plurality of light-emitting elements ED to be evenly diffused and extracted to the outside of the display device 1000, thereby improving the luminance uniformity of the display device 1000.

The third optical layer 117c may be formed of an organic insulating material in which fine particles are dispersed. However, embodiments of the present specification are not limited thereto. For example, the third optical layer 117c may be formed of siloxane in which fine metal particles, such as titanium dioxide (TiO₂) particles, are dispersed; however, embodiments of the present specification are not limited thereto. For example, the third optical layer 117c may be formed of the same material as the first optical layer 117a, but embodiments of the present specification are not limited thereto. For example, the third optical layer 117c may be a diffusion layer or an upper surface diffusion layer; however, embodiments of the present specification are not limited thereto.

According to the present specification, light emitted from the plurality of light-emitting elements ED may be scattered by the fine particles dispersed in the third optical layer 117c and emitted to the outside of the display device 1000. The third optical layer 117c may evenly mix the light emitted from the plurality of light-emitting elements ED, thereby further improving the luminance uniformity of the display device 1000. In addition, scattering the light using the plurality of fine particles may enhance the light extraction efficiency of the display device 1000, thereby enabling the display device 1000 to operate with lower power consumption.

In the display area AA, a black matrix BM may be located on the second electrode CE2, the first optical layer 117a, the second optical layer 117b, and the third optical layer 117c. For example, the black matrix BM may fill the contact hole of the second optical layer 117b. Because the black matrix BM is configured to cover the display area AA, the black matrix BM may reduce color mixing of light from the plurality of sub-pixels and reflection of external light. For example, the black matrix BM may also be located in the contact hole through which the second electrode CE2 and the contact electrode CCE are connected, thereby preventing or reducing light leakage between adjacent sub-pixels.

For example, the black matrix BM may be formed of an opaque material. However, embodiments of the present specification are not limited thereto. For instance, the black matrix BM may be an organic insulating material containing a black pigment or a black dye, but embodiments of the present specification are not limited thereto.

In the display area AA, a cover layer 118 may be located on the black matrix BM. The cover layer 118 may protect components provided under the cover layer 118. For example, the cover layer 118 may be formed of an organic insulating material; however, embodiments of the present specification are not limited thereto. For example, the cover layer 118 may be formed of photoresist, polyimide (PI), a photoacryl-based material, or the like, but embodiments of the present specification are not limited thereto. For instance, the cover layer 118 may be an overcoating layer, an insulating layer, or the like; however, embodiments of the present specification are not limited thereto.

The polarizing layer 293 may be located on the cover layer 118 via a first adhesive layer 291. The cover 120 may be located on the polarizing layer 293 via a second adhesive layer 295. For example, the first adhesive layer 291 and the second adhesive layer 295 may each include an optically clear adhesive (OCA), an optically clear resin (OCR), a pressure-sensitive adhesive (PSA), or the like. However, embodiments of the present specification are not limited thereto.

According to the present specification, in the second non-display area NA2, the plurality of pad electrodes PE may be arranged on the third insulating layer 115c. For example, at least a portion of each of the plurality of pad electrodes PE may be exposed from the passivation layer 116. For example, the plurality of pad electrodes PE may be electrically connected to the second-fourth connection wires 122d through contact holes of the third insulating layer 115c.

An adhesive layer ACF may be located on the plurality of pad electrodes PE. The adhesive layer ACF may be an adhesive layer in which conductive balls are dispersed in an insulating material, but embodiments of the present specification are not limited thereto. In the case where heat or pressure is applied to the adhesive layer ACF, the conductive balls in the area where heat or pressure is applied may be electrically connected, thereby exhibiting conductive properties. The flexible circuit board (or the flexible film) CB may be attached or bonded to the plurality of pad electrodes PE by locating the adhesive layer ACF between the plurality of pad electrodes PE and the flexible circuit board (or flexible film) CB. For example, the adhesive layer ACF may be an anisotropic conductive film (ACF), but embodiments of the present specification are not limited thereto.

The flexible circuit board (or a flexible film) CB may be located on the adhesive layer ACF. The flexible circuit board (or the flexible film) CB may be electrically connected to the plurality of pad electrodes PE through the adhesive layer ACF. Accordingly, signals output from the flexible circuit board (or the flexible film) CB and the printed circuit board may be transmitted to the pixel driving circuit PD in the display area AA through the plurality of pad electrodes PE, the second-fourth connection wire 122d, the second-third connection wire 122c, the second-second connection wire 122b, and the second-first connection wires 122a.

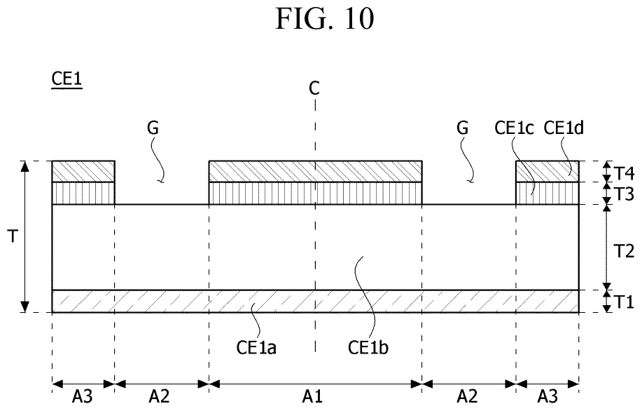

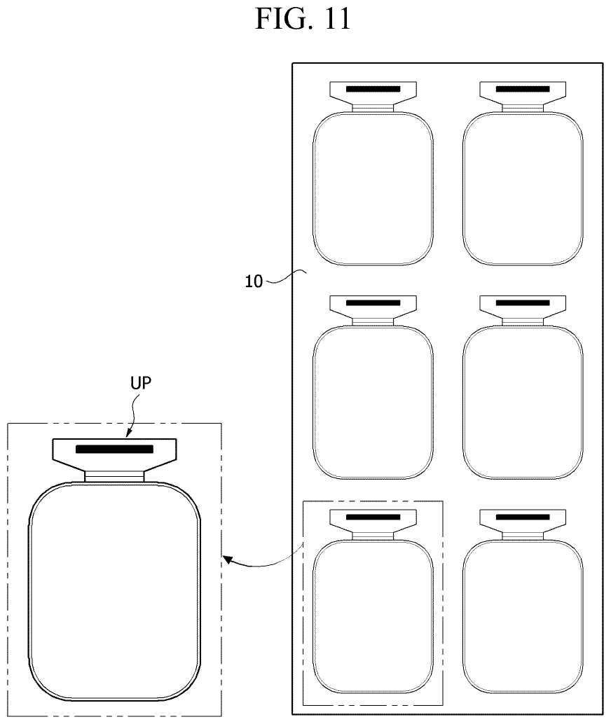

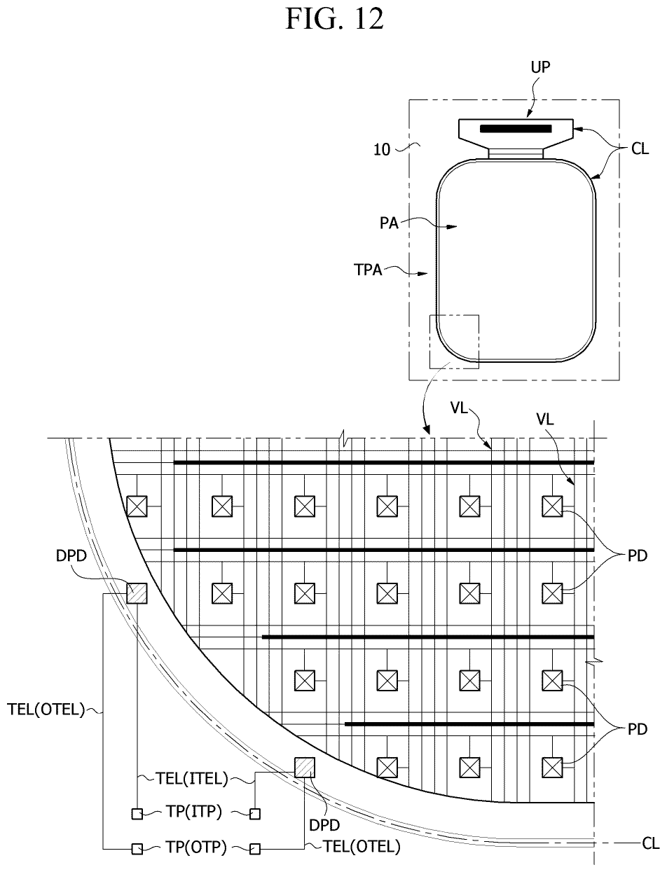

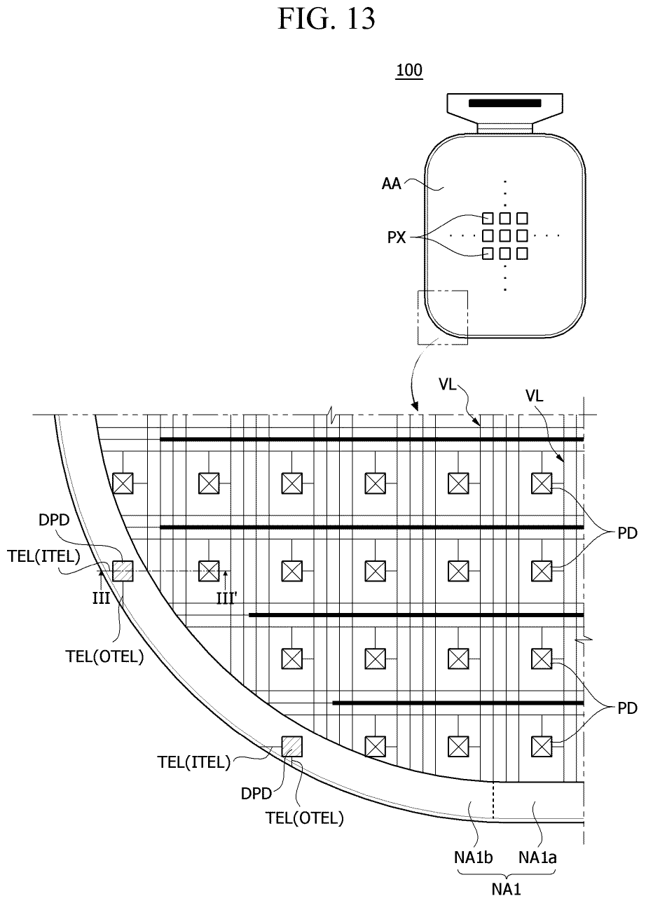

FIG. 11 is a diagram illustrating a plurality of half-finished panels disposed on a mother substrate. FIG. 12 is a diagram illustrating an embodiment for a disposition relationship between a half-finished panel and a test pad on a mother substrate. FIG. 13 is a diagram illustrating a display panel separated from the mother substrate. FIG. 14 is a cross-sectional view of the display apparatus according to the present specification. For example, FIG. 14 is a diagram illustrating a cross section of the display panel taken along line III-III′ of FIG. 13. The display panel 100 illustrated in FIG. 13 may be a display panel according to a first example embodiment.

As shown in FIGS. 11 to 13, a plurality of half-finished panels UP, test pads TP, and the like may be configured on a mother substrate 10. Through a cutting process using laser or the like, one display panel 100 may be separated from the mother substrate 10. For example, a cutting apparatus using laser or the like may separate each display panel 100 from the mother substrate 10 along a trimming line. The mother substrate 10 may be formed through a process of forming metals corresponding to various electrodes or wires and various insulation films on one substrate, a transfer process of the light-emitting elements ED and the pixel driving circuits PD, and the like. The trimming line may be a cutting line.

Accordingly, an etching process, a cutting process, a coating process, and the like may be performed on the mother substrate to manufacture the half-finished panel UP, and the half-finished panel UP may be irradiated with laser along the cutting line CL to form the display panel 100 according to the present specification, but the present specification is not necessarily limited thereto.

The mother substrate 10 according to the embodiment of the present specification may be divided into a panel area PA and a test pad area TPA with the cutting line CL as a reference. The half-finished panel UP may be disposed in the panel area PA, and a plurality of test pads TP may be disposed in the test pad area TPA. Dummy pixel driving circuits DPD of the half-finished panel UP and the test pads TP may be electrically connected by test wires TEL. Accordingly, the test wires may be disposed across the panel area PA and the test pad area TPA.

As shown in FIGS. 11 to 14, since the half-finished panel UP according to the embodiment of the present specification is cut along the cutting line CL, the half-finished panel UP may include components that configure the display panel 100. For example, the half-finished panel UP may include a substrate 110, a first buffer layer 111a disposed on the substrate 110, a second buffer layer 111b, an adhesive layer 112, a pixel driving circuit PD, a first protection layer 113a, a second protection layer 113b, a third protection layer 114, a first insulation layer 115a, a second insulation layer 115b, a third insulation layer 115c, a passivation layer 116, a plurality of first connection wires 121, a plurality of second connection wires 122, a plurality of signal wires TL, a plurality of communication wires NL, a plurality of first electrodes CE1, a plurality of banks BNK, a plurality of light-emitting elements ED, a plurality of second electrodes CE2, a plurality of solder patterns SDPb, a plurality of contact electrodes CCE, a first optical layer 117a, a second optical layer 117b, a third optical layer 117c, a black matrix BM, at least one dummy pixel driving circuit DPD, a plurality of test wires TEL, and the like, but the embodiments of the present specification are not limited thereto. In cutting the mother substrate 10 along the cutting line CL, some of the test wires TEL may remain in the display panel 100. A protection layer made of an inorganic insulation material may be further disposed on the pixel driving circuit PD to protect the pixel driving circuit PD. A protection layer made of an inorganic insulation material may be further disposed on the dummy pixel driving circuit DPD to protect the dummy pixel driving circuit DPD. For example, the protection layer may be a packing layer or an insulation layer, but the embodiments of the present specification are not limited thereto.

The test pads TP may be disposed in the test pad area TPA and may be used for an auto-probe test. The test pads TP may be electrically connected to the dummy pixel driving circuits DPD by the test wires TEL. Accordingly, it is possible to check whether the dummy pixel driving circuits DPD are defective, using the test pads TP and the test wires TEL. For example, it is possible to check the defects in the dummy pixel driving circuits DPD such as internal disconnection through resistance measurement of the dummy pixel driving circuits DPD using the test pads TP and the test wires TEL.

A plurality of pixel driving circuits PD may be disposed on the substrate 110 of the display panel 100 in a matrix through the transfer process. Since the pixel driving circuits PD before the transfer process grow on one wafer together under the same conditions, when one of the pixel driving circuits PD is determined to be defective, there is a high possibility that other pixel driving circuits PD are also defective. Then, since the defects in the pixel driving circuits PD cause a defect in the display apparatus, the reliability of the display apparatus may be deteriorated.

It is possible to improve reliability for a manufacturing process by reducing a defective rate of the display apparatus due to the defects in the pixel driving circuits PD disposed on the substrate 110 of the display panel 100. To decrease or reduce the defective rate of the display apparatus due to the defects in the pixel driving circuits PD, it is possible to predict whether the pixel driving circuits PD are defective, by measuring the resistance of at least one dummy pixel driving circuit DPD disposed on the display panel 100. Accordingly, by stopping the progress of a process on the display panel 100 in which at least one dummy pixel driving circuit DPD is defective, it is possible to improve the quality of the display panel 100 according to the embodiment of the present specification and improve the reliability. For example, it is possible to improve the reliability for the manufacturing process by reducing the defective rate of the display apparatus due to the defects in the pixel driving circuits PD disposed on the substrate of the display panel 100. For example, it is possible to improve the reliability of the quality of the display apparatus through determination of whether the pixel driving circuits are defective, based on measurement of the resistance of a plurality of dummy pixel driving circuits DPD disposed in the half-finished display panel.

Since it is possible to determine whether the pixel driving circuits PD are defective, by determining the defects in the dummy pixel driving circuits DPD with priority before the transfer process of the light-emitting elements ED, or the like, it is possible to determine whether to progress a process of forming metals corresponding to various electrodes or wires and various insulation films, the transfer process of the light-emitting elements ED and the pixel driving circuits PD, and the like. For example, when the dummy pixel driving circuits DPD are determined to be defective, the process of forming metals corresponding to various electrodes or wires and various insulation films, the transfer process of the light-emitting elements ED and the pixel driving circuits PD, and the like may not progress. Accordingly, it is possible to reduce greenhouse gases from the viewpoint of producing the display panel 100.

Through the cutting process along the cutting line CL, one display panel 100 may be separated from the mother substrate 10. Accordingly, the display panel 100 may include the substrate 110, the first buffer layer 111a disposed on the substrate 110, the second buffer layer 111b, the adhesive layer 112, the pixel driving circuit PD, the first protection layer 113a, the second protection layer 113b, the third protection layer 114, the first insulation layer 115a, the second insulation layer 115b, the third insulation layer 115c, the passivation layer 116, a plurality of first connection wires 121, a plurality of second connection wires 122, a plurality of signal wires TL, a plurality of communication wires NL, a plurality of first electrodes CE1, a plurality of banks BNK, a plurality of light-emitting elements ED, a plurality of second electrodes CE2, a plurality of solder patterns SDPb, a plurality of contact electrodes CCE, the first optical layer 117a, the second optical layer 117b, the third optical layer 117c, the black matrix BM, at least one dummy pixel driving circuit DPD, a plurality of test wires TEL, and the like, but the embodiments of the present specification are not limited thereto. In cutting the mother substrate 10 along the cutting line CL, end portions of the test wires TEL may be exposed.

The dummy pixel driving circuit DPD may be disposed in the same layer as the pixel driving circuit PD. The dummy pixel driving circuits DPD may be disposed apart from the pixel driving circuit PD. For example, the pixel driving circuit PD and the dummy pixel driving circuit DPD may be disposed on the adhesive layer 112.

Unlike the pixel driving circuits PD to which the driving wires VL, the signal wires for controlling light emission on/off and light emission time of the light-emitting elements, and the like are connected, only the test wires TEL are connected to the dummy pixel driving circuits DPD. For this reason, the pixel driving circuits PD and the dummy pixel driving circuits DPD disposed on the adhesive layer 112 may be electrically separated. Accordingly, the driving wires VL connected to the pixel driving circuits PD may be electrically separated from the test wires TEL connected to the dummy pixel driving circuits DPD.

Taking the disposition of the driving wires VL and the like into account, it is difficult to connect the test wires TEL to the pixel driving circuits PD to directly measure the resistance of the pixel driving circuits PD. For example, when the test wires TEL are connected to a plurality of pixel driving circuits PD, respectively, the test wires TEL may interfere with the driving wires VL, the link wires LL, and the like for disposition. For this reason, it is difficult to connect the test wires TEL directly to the pixel driving circuits PD, respectively.

Accordingly, the dummy pixel driving circuits DPD may be disposed in a first non-display area NA1 apart from the pixel driving circuits PD disposed in a display area AA. For example, the first non-display area NA1 may include a first area NA1a and a second area NA1b. The first area NA1a may be a linear section of the first non-display area NA1 and the second area NA1b may be a curved section of the first non-display area NA1. Accordingly, the dummy pixel driving circuits DPD may be disposed in the second area NA1b including a curved section, for example, a corner portion or an edge portion of the display panel 100.

The test wires TEL may be disposed on the adhesive layer 112. Then, the test wires TEL may be connected to the dummy pixel driving circuits DPD.

The test wires TEL may be disposed toward the outside from the dummy pixel driving circuits DPD. The inside may be a direction toward a center on a plane of the display panel 100 and the outside may be a direction opposite to the inside, but the embodiments of the present specification are not limited thereto.

The test wires TEL may be disposed on the second protection layer 113b. For example, the test wires TEL may be formed of the same conductive material and through the same process as a first-first connection wire 121a, but the embodiments of the present specification are not limited thereto. For example, the test wires TEL may be formed of a conductive material having excellent flexibility such as gold (Au), silver (Ag), or aluminum (Al), but the embodiments of the present specification are not limited thereto. As another example, the test wires TEL may be formed of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto.

The test wires TEL may include a first test wire ITEL connected to one side of one dummy pixel driving circuit DPD and a second test wire OTEL connected to the other side of the dummy pixel driving circuit DPD. For example, a current input to the first test wire ITEL may flow through the dummy pixel driving circuit DPD and may be then output from the second test wire OTEL, but the present specification is not necessarily limited thereto. The first test wire ITEL may be an input test wire. The second test wire OTEL may be an output test wire.

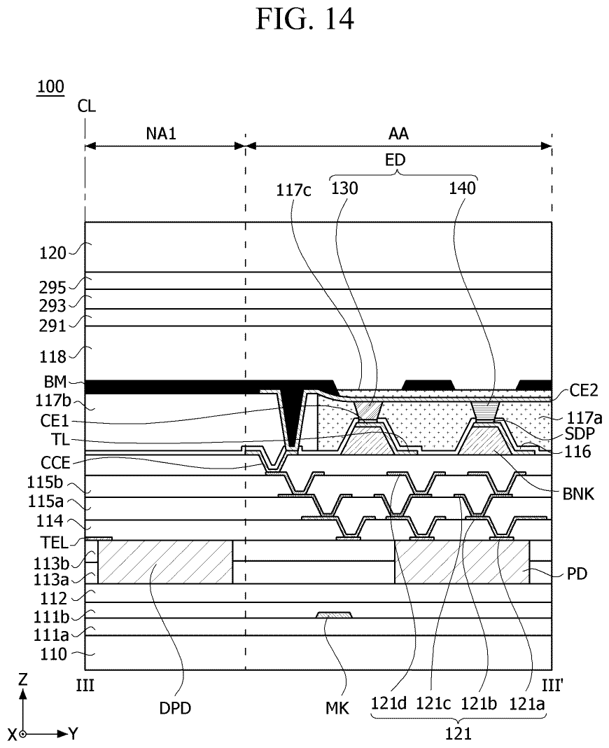

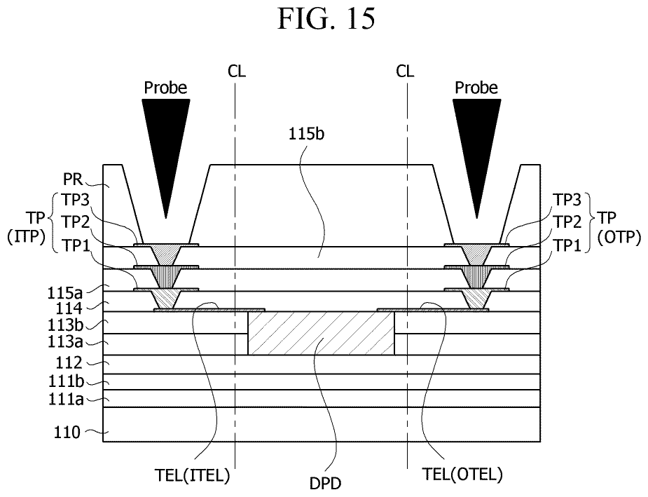

FIG. 15 is a diagram illustrating resistance measurement of a dummy pixel driving circuit. FIG. 16 is a diagram illustrating test pads separated through the cutting process. For example, FIG. 15 may be a diagram illustrating the resistance measurement of the dummy pixel driving circuit DPD on the mother substrate 10 before a manufacturing process of metal wires such as the contact electrode CCE and the signal wire TL.

The test pads TP may be electrically connected to the test wires TEL and may be used for an auto-probe test. For example, the test pads TP may include a first test pad ITP electrically connected to the first test wire ITEL and a second test pad OTP electrically connected to the second test wire OTEL. The first test pad ITP may be an input test pad. The second test pad OTP may be an output test pad.

As shown in FIG. 15, the test pad TP may include a first test pad TP1 on the third protection layer 114, a second test pad TP2 on the first insulation layer 115a, and a third test pad TP3 on the second insulation layer 115b, but the embodiments of the present specification are not limited thereto. For example, the resistance of the dummy pixel driving circuit DPD may be measured in a state in which only the first test pad TP1 electrically connected to the test wires TEL is disposed, but the present specification is not necessarily limited thereto.

The first test pad TP1 may be disposed on the third protection layer 114 and may be electrically connected to the test wire TEL. For example, a part of the first test pad TP1 may be electrically connected to the test wire TEL through a contact hole in the third protection layer 114. For example, the first test pad TP1 may be a first-second connection wire 121b. For example, the first test pad TP1 may be formed similarly in forming the first-second connection wire 121b, but the embodiments of the present specification are not limited thereto.

The second test pad TP2 may be disposed on the first insulation layer 115a and may be electrically connected to the first test pad TP1. For example, a part of the second test pad TP2 may be electrically connected to the first test pad TP1 through a contact hole in the first insulation layer 115a. For example, the second test pad TP2 may be a first-third connection wire 121c. For example, the second test pad TP2 may be formed similarly in forming the first-third connection wire 121c, but the embodiments of the present specification are not limited thereto.

The third test pad TP3 may be disposed on the second insulation layer 115b and may be electrically connected to the second test pad TP2. For example, a part of the third test pad TP3 may be electrically connected to the second test pad TP2 through a contact hole in the second insulation layer 115b. For example, the third test pad TP3 may be a first-fourth connection wire 121d. For example, the third test pad TP3 may be formed similarly in forming the first-fourth connection wire 121d, but the embodiments of the present specification are not limited thereto.

An organic material layer PR in which a hole is formed may be disposed on the test pad TP to guide a probe that is used for the auto-probe test. For example, the probe may be configured in a corner portion (or an edge portion) of the display panel, but the embodiments of the present specification are not limited thereto.

The organic material layer PR may contain an organic insulation material. For example, the organic material layer PR may be photoresist, but the present specification is not limited thereto. For example, the organic material layer PR may be the third insulation layer 115c.

Accordingly, determination of whether the dummy pixel driving circuits DPD are defective may be made by applying a current to the test pad TP through the hole in the organic material layer PR and measuring the resistance of the dummy pixel driving circuit DPD. For example, when at least one dummy pixel driving circuit DPD is determined to be defective, there is a probability that the pixel driving circuits PD are also defective. For this reason, it is possible to improve the yield and the reliability of the display apparatus by stopping the progress of the manufacturing process of the display panel 100. For example, when all dummy pixel driving circuits DPD are not defective, the manufacturing process of the display panel 100 can be performed and the display panel 100 may be separated from the mother substrate 10 through the cutting process. As illustrated in FIG. 16, end portions of the test wires TEL may be exposed by the cutting process.

As shown in FIGS. 12 and 15, the display apparatus according to the embodiment of the present specification can measure the resistance of the dummy pixel driving circuit DPD by a two-terminal resistance measurement method using measurement equipment. The two-terminal resistance measurement method is a method that is most used in measuring resistance and connects a + probe and a − probe to both ends of a test resistor, respectively, in a form in which two pins of a constant current source and two pins of a voltmeter are connected. According to the two-terminal measurement method, the resistance of a measurement line (probe, cable, or the like) and contact resistance may be added to a test resistance value to cause a measurement error.

In the case of the display panel 100 according to the embodiment of the present specification, since the dummy pixel driving circuits DPD are disposed in the first non-display area NA1, a degree of freedom for the disposition of the test wires TEL can be improved. Accordingly, the resistance of the dummy pixel driving circuit (DPD) can be measured with higher accuracy using a four-terminal resistance measurement method more accurate than the two-terminal resistance measurement method. The four-terminal resistance measurement method is a method that is usually used to measure resistance with no errors, two current terminals for supplying a constant current and two voltage terminals connected to a voltmeter may be configured and connected to a test resistor. The four-terminal resistance measurement method may be similar to the two-terminal resistance measurement method in that a current is applied from a constant current source, a voltage is generated across both ends of the test resistor, and the voltage across both ends of the test resistor is measured by the voltmeter. However, in the four-terminal resistance measurement method, unlike the two-terminal resistance measurement method, both ends of the constant current source and both ends of the voltmeter are not connected, and since the impedance of the voltmeter is set to be high, no current may flow into the voltmeter. Accordingly, there is no influence of the probe for measurement and the cable in the two-terminal resistance measurement method, thereby reducing a measurement error.

According to the present specification, by minimizing or reducing the possibility that a plurality of pixel driving circuits PD are defective, based on the determination of the defect in the dummy pixel driving circuit DPD before a process of separating one display panel 100 such as trimming, it is possible to optimize the process of the display apparatus and to reduce or minimize the possibility that the display apparatus is defective.

According to the present specification, by determining whether the pixel driving circuits are defective, on the basis of the measurement of the resistance of each of a plurality of dummy pixel driving circuits DPD disposed in the half-finished display panel, and when at least one dummy pixel driving circuit DPD is defective, it is possible to improve the yield of the display apparatus that is actually provided as a product by stopping the progress of the process of the display panel 100.

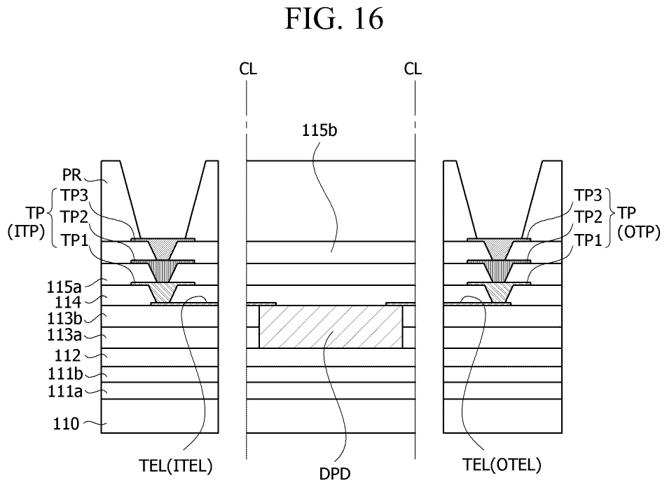

FIG. 17 is a diagram illustrating another embodiment of a disposition relationship between a half-finished panel and test pads on a mother substrate. For example, FIG. 17 is a diagram illustrating a half-finished panel UP and test pads that are measured by a four-terminal resistance measurement method.

In describing the four-terminal resistance measurement method illustrated in FIG. 17, the substantially same components in the two-terminal resistance measurement method illustrated in FIG. 12 and the four-terminal resistance measurement method illustrated in FIG. 17 are represented by the same reference numbers, and detailed description thereof will not be repeated.

As shown in FIG. 17, the half-finished panel UP may include a substrate 110, a first buffer layer 111a disposed on the substrate 110, a second buffer layer 111b, an adhesive layer 112, a pixel driving circuit PD, a first protection layer 113a, a second protection layer 113b, a third protection layer 114, a first insulation layer 115a, a second insulation layer 115b, a third insulation layer 115c, a passivation layer 116, a plurality of first connection wires 121, a plurality of second connection wires 122, a plurality of signal wires TL, a plurality of communication wires NL, a plurality of first electrodes CE1, a plurality of banks BNK, a plurality of light-emitting elements ED, a plurality of second electrodes CE2, a plurality of solder patterns SDPb, a plurality of contact electrodes CCE, a first optical layer 117a, a second optical layer 117b, a third optical layer 117c, a black matrix BM, at least one dummy pixel driving circuit DPD, a plurality of test wires TEL, and the like, but the present specification is not limited thereto. The test wires TEL may include a first test wire ITEL and a second test wire OTEL connected to one dummy pixel driving circuit DPD.

In the test pad area TPA of the mother substrate 10, third test wires BTEL that branch off from the test wires TEL, respectively, may be further disposed. The third test wires BTEL may be branch test wires BTEL.

The test pads TP may be disposed in the test pad area TPA. The test pads TP may include first test pads ITP and second test pads OTP. For example, for the four-terminal resistance measurement method, the first test pads ITP may include a first input test pad ITP1 and a second input test pad ITP2. The second test pads OTP may include a first output test pad OTP1 and a second output test pad OTP2.

Each of the first input test pad ITP1, the second input test pad ITP2, the first output test pad OTP1, and the second output test pad OTP2 may include a first test pad TP1 on the third protection layer 114, a second test pad TP2 on the first insulation layer 115a, and a third test pad TP3 on the second insulation layer 115b, but the embodiments of the present specification are not limited thereto.

The third test wires BTEL may branch off from the test wires TEL. Each of the third test wires BTEL may be connected to any one of the test pads TP to which the test wires TEL are not connected. For example, the third test wires BTEL may include an input branch test wire IBTEL that connects the first test wire ITEL and the second input test pad ITP2, and an output branch test wire OBTEL that connects the second test wire OTEL and the second output test pad OTP2. The first test wire ITEL may connect the dummy pixel driving circuit DPD and the first input test pad ITP1. The second test wire OTEL may connect the dummy pixel driving circuit DPD and the first output test pad OTP1.

Accordingly, the display panel 100 according to the embodiment of the present specification may include the test wires TEL.

The test wires TEL may be disposed outward such that the resistance of the dummy pixel driving circuit DPD can be measured by not only the two-terminal resistance measurement method but also the four-terminal resistance measurement method.

The test wires TEL of the display panel 100 according to the embodiment of the present specification may be exposed to the outside. For this reason, the test wires TEL exposed to the outside may be used as a penetration path through which moisture, impurities, and/or the like penetrate inside the display panel 100.

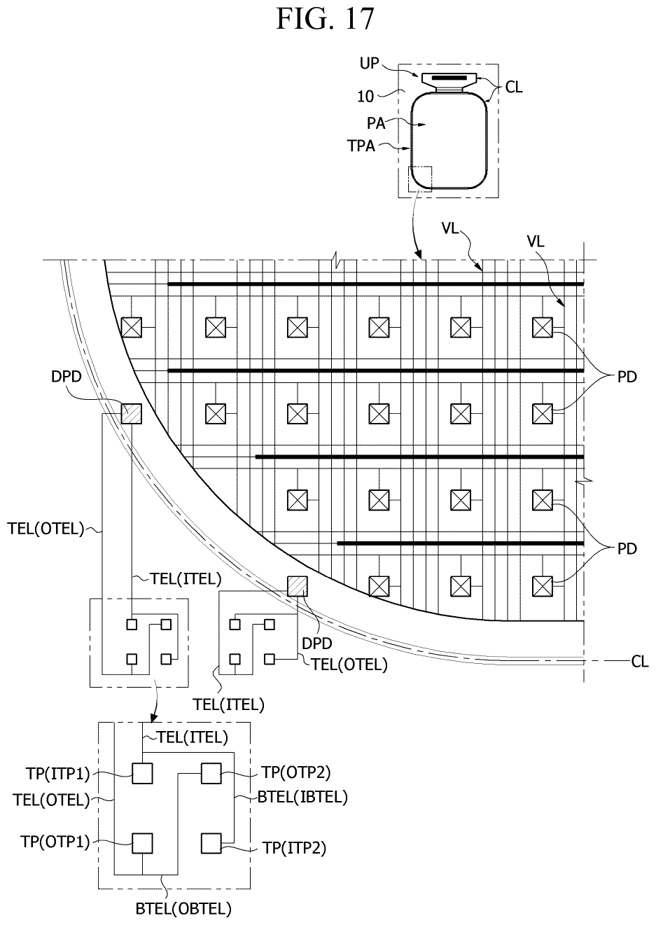

FIG. 18 is a diagram illustrating a display apparatus according to another embodiment of the present specification.

As shown in FIG. 18, the display panel 100 according to the embodiment of the present specification disposes a plurality of first connection wires 121 in an outer portion of the display area AA along the circumference of the display area AA, thereby preventing or reducing moisture, impurities, and/or the like from penetrating inside the display panel 100. For example, the display panel 100 according to the embodiment of the present specification disposes the first connection wires 121 along the circumference of the display area AA to configure a passivation metal boundary (PMB) structure. For this reason, it is possible to prevent or reduce moisture, impurities, and/or the like from penetrating inside the display panel 100 during trimming. Accordingly, it is possible to protect the organic layers and/or the wires in the display panel exposed during trimming from moisture and/or impurities. For example, the passivation metal boundary PMB may be configured with the first connection wires 121 that are disposed on the second protection layer 113b disposed between the pixel driving circuits PD disposed in the outer portion of the display area AA and the dummy pixel driving circuit DPD. For example, the passivation metal boundary PMB may be a protection layer or a protection wire, but the embodiments of the present specification are not limited thereto.

The passivation metal boundary PMB implemented by a plurality of first connection wires 121 may be formed in an arch shape in which an opening is formed on a side facing the pad portion PAD, but the present specification is not necessarily limited thereto. For example, the passivation metal boundary PMB may be configured in a closed loop structure such as a ring shape. For example, while the passivation metal boundary PMB is formed continuously along the outer portion of the display area AA as an example, but the present specification is not necessarily limited thereto. For example, the passivation metal boundary (PMB) structure may be implemented by a plurality of first connection wires 121 spaced apart from each other along the outer portion of the display area AA.

The passivation metal boundary (PMB) may be formed in a stepwise shape in cross-sectional view. For example, the first connection wires 121 may include a first-first connection wire 121a, a first-second connection wire 121b, a first-third connection wire 121c, and a first-fourth connection wire 121d, and the passivation metal boundary (PMB) may be formed in a stepwise shape in cross-sectional view by these first connection wires 121 and contact holes formed for electrical connection of these first connection wires (see FIG. 18). For example, since the passivation metal boundary (PMB) is configured in a stepwise shape, it is possible to more efficiently protect the organic layers and/or the wires in the exposed display panel during trimming from moisture. For example, the first connection wire 121 extends a length of a path through which moisture, impurities, and/or the like penetrate, by the first-first connection wire 121a, the first-second connection wire 121b, the first-third connection wire 121c, the first-fourth connection wire 121d, and the contact holes formed for electrical connection thereof, thereby more effectively preventing or reducing moisture, impurities, and/or the like from penetrating inside the display panel 100. Since a plurality of first connection wires 121 are disposed along the circumference of the display area AA, it is possible to more effectively prevent or reduce penetration of moisture, impurities, and/or the like.

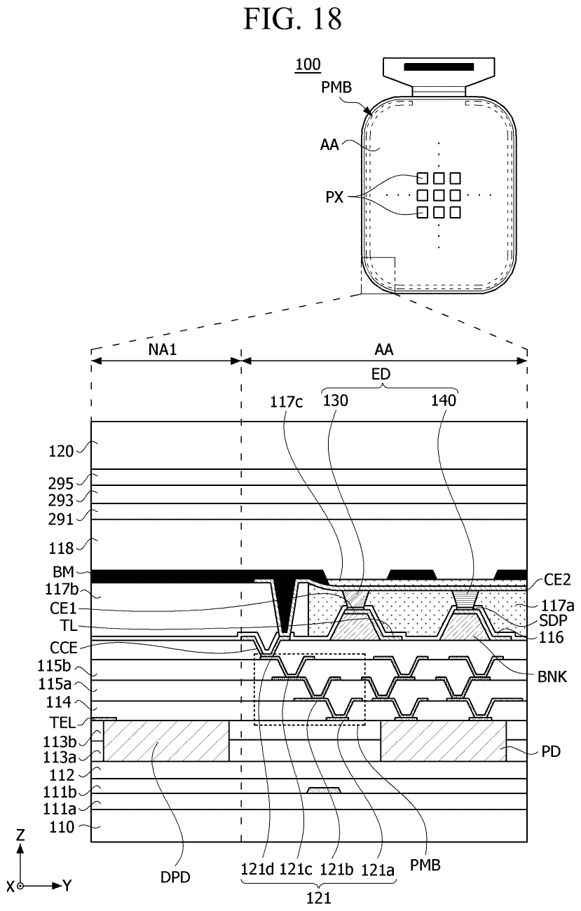

FIG. 19 is a diagram illustrating a coating layer that is disposed in the display panel according to the embodiment.

As shown in FIG. 19, the display panel 100 may further include a coating layer 300 that is disposed to cover the exposed end portion of the test wire TEL.

The coating layer 300 may cover at least one side surface or the entire side surface of the display panel 100, but the present specification is not necessarily limited thereto. For example, the coating layer 300 may be disposed only on the side surfaces of the second protection layer 113b and the third protection layer 114 to cover the end portion of the test wire TEL, but the present specification is not necessarily limited thereto. The coating layer 300 may be a protection layer.

The coating layer 300 may be formed of an inorganic insulation material, but the present specification is not necessarily limited thereto.

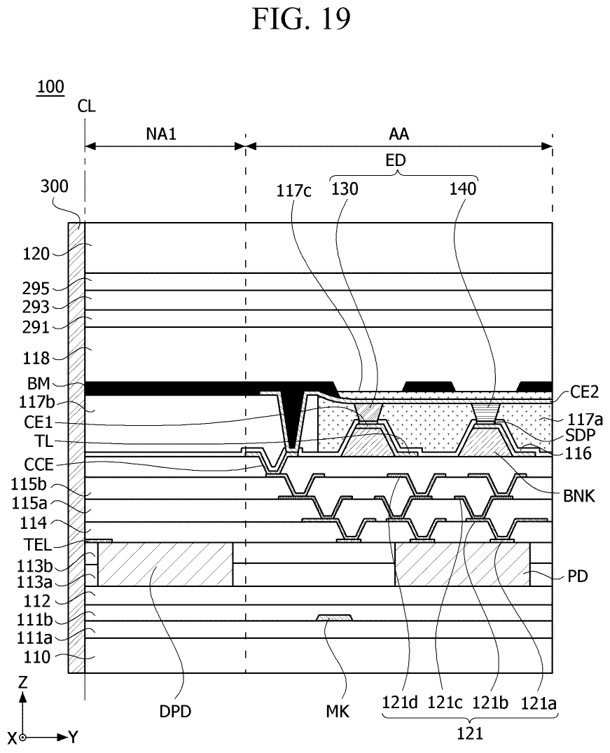

FIG. 20 is a diagram illustrating another embodiment of the display apparatus according to the embodiment of the present specification. A display panel 100a illustrated in FIG. 20 may be a display panel according to a second example embodiment.

In comparison of the display panel 100 according to the first example embodiment illustrated in FIG. 13 and the display panel 100a according to the second example embodiment illustrated in FIG. 20 with reference to FIGS. 8A, 8B, 13, and 20, the display panel 100a according to the second example embodiment may further include a test connection wire TCEL that connects a first dummy pixel driving circuit DPD1 and a second dummy pixel driving circuit DPD2.

In describing the display panel 100a according to the second example embodiment with reference to FIGS. 8A, 8B, 13, and 20, the substantially same components of the display panel 100 according to the first example embodiment and the display panel 100a according to the second example embodiment are represented by the same reference numbers, and detailed description thereof will not be repeated.

The display panel 100a may include a substrate 110, a first buffer layer 111a disposed on the substrate 110, a second buffer layer 111b, an adhesive layer 112, a pixel driving circuit PD, a first protection layer 113a, a second protection layer 113b, a third protection layer 114, a first insulation layer 115a, a second insulation layer 115b, a third insulation layer 115c, a passivation layer 116, a plurality of first connection wires 121, a plurality of second connection wires 122, a plurality of signal wires TL, a plurality of communication wires NL, a plurality of first electrodes CE1, a plurality of banks BNK, a plurality of light-emitting elements ED, a plurality of second electrodes CE2, a plurality of solder patterns SDPb, a plurality of contact electrodes CCE, a first optical layer 117a, a second optical layer 117b, a third optical layer 117c, a black matrix BM, a first dummy pixel driving circuit DPD1, a second dummy pixel driving circuit DPD2, a plurality of test wires TEL, a test connection wire TCEL, and the like, but the embodiments of the present specification are not limited thereto. In cutting the mother substrate 10 along the cutting line CL, the end portions of the test wires TEL may be exposed.

The first dummy pixel driving circuit DPD1 and the second dummy pixel driving circuit DPD2 may be disposed in the same layer as the pixel driving circuit PD. The first dummy pixel driving circuit DPD1 and the second dummy pixel driving circuit DPD2 may be disposed apart from the pixel driving circuit DPD. For example, the pixel driving circuit PD, the first dummy pixel driving circuit DPD1, and the second dummy pixel driving circuit DPD2 may be disposed apart from each other on the adhesive layer 112.

The first dummy pixel driving circuit DPD1 and the second dummy pixel driving circuit DPD2 may be disposed in the first non-display area NA1 apart from each other. For example, the first dummy pixel driving circuit DPD1 and the second dummy pixel driving circuit DPD2 may be disposed on a corner side (or in a corner portion, on an edge side, or in an edge portion) of the display panel 100a. For example, since the first dummy pixel driving circuit DPD1 and the second dummy pixel driving circuit DPD2 may be disposed on the corner side (or on the edge side) of the display panel 100a, four first dummy pixel driving circuits DPD1 and four second dummy pixel driving circuit DPD2 may be disposed, but the present specification is not limited thereto. For example, since the wires for the probe are configured in the corner portion (or the edge portion) of the display panel 100a, a defect in one of the first dummy pixel driving circuit DPD1 and the second dummy pixel driving circuit DPD2 may be detected.

The test wires TEL may be disposed on the adhesive layer 112 to be connected to the first dummy pixel driving circuit DPD1 and the second dummy pixel driving circuit DPD2. The test wires TEL may be disposed toward the outside from the first dummy pixel driving circuit DPD1 and the second dummy pixel driving circuit DPD2.

The test wires TEL may include a first test wire ITEL connected to the first dummy pixel driving circuit DPD1 and a second test wire OTEL connected to the second dummy pixel driving circuit DPD2. For example, a current input to the first test wire ITEL may flow through the first dummy pixel driving circuit DPD1, the test connection wire TCEL, and the second dummy pixel driving circuit DPD2 and may be then output from the second test wire OTEL, but the present specification is not necessarily limited thereto. An end portion of the first test wire ITEL connected to the first dummy pixel driving circuit DPD1 and an end portion of the second test wire OTEL connected to the second dummy pixel driving circuit DPD2 may be exposed. The exposed end portions of the first test wire ITEL and the second test wire OTEL may be covered with a coating layer 300.

The test connection wire TCEL may electrically connect the first dummy pixel driving circuit DPD1 and the second dummy pixel driving circuit DPD2.

The test connection wire TCEL may be disposed in the first non-display area NA1. The test connection wire TCEL may be disposed on the adhesive layer 112. For example, the test connection wire TCEL may be formed of the same conductive material and through the same process as the first-first connection wire 121a, but the embodiments of the present specification are not limited thereto. For example, the test connection wire TCEL may be formed of a conductive material having excellent flexibility such as gold (Au), silver (Ag), or aluminum (Al), but the embodiments of the present specification are not limited thereto. As another example, the test connection wire TCEL may be formed of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto.

In FIG. 20, while the test connection wire TCEL includes a linear section and a curved section of the display panel as an example, but the present specification is not necessarily limited thereto. For example, the test connection wire TCEL may be formed only with a plurality of linear sections using a bending structure of the display panel.

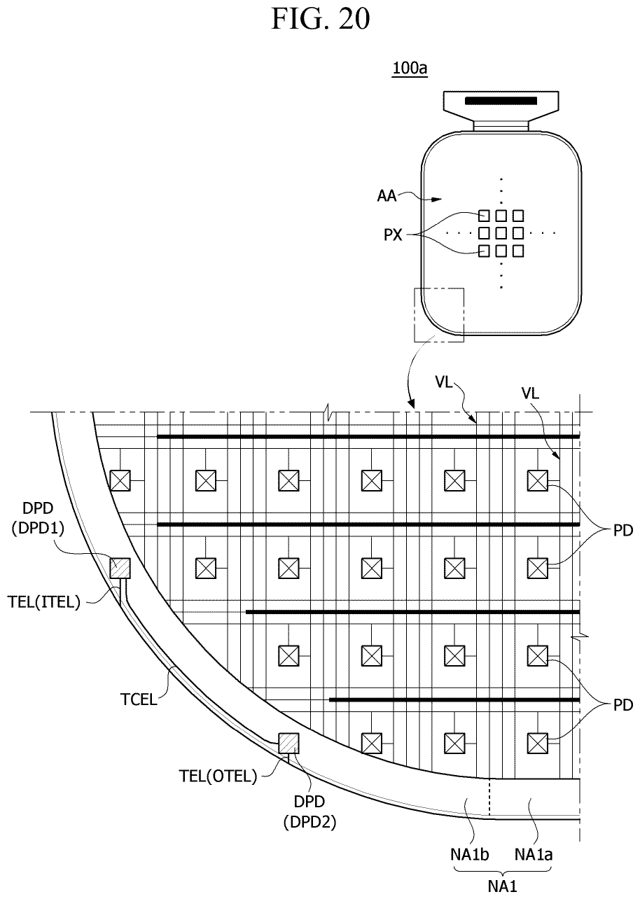

FIG. 21 is a diagram illustrating another embodiment of a disposition relationship between a half-finished panel and test pads on a mother substrate. For example, FIG. 21 is a diagram illustrating an embodiment of a disposition relationship between a half-finished panel and test pads for the display panel 100a according to the second example embodiment.

As shown in FIG. 21, the display apparatus according to the embodiment of the present specification can measure the resistance of the first dummy pixel driving circuit DPD1, the second dummy pixel driving circuit DPD2, and the like by the two-terminal resistance measurement method using measurement equipment.

A plurality of half-finished panels UP, test pads TP, and the like may be configured on a mother substrate 10. One display panel 100a may be separated from the mother substrate 10 along a cutting line CL.

The mother substrate 10 according to the embodiment of the present specification may include a panel area PA and a test pad area TPA with the cutting line CL as a reference. In the panel area PA, the half-finished panel UP may be disposed. In the test pad area TPA, a plurality of test pads TP may be disposed. The first dummy pixel driving circuit DPD1 and the second dummy pixel driving circuit DPD2 of the half-finished panel UP may be electrically connected to the test pads TP via the test wires TEL. For example, the test pads TP may include a first test pad ITP electrically connected to a first test wire ITEL and a second test pad OTP electrically connected to the second test wire OTEL. Accordingly, the test wires TEL may be disposed across the panel area PA and the test pad area TPA.

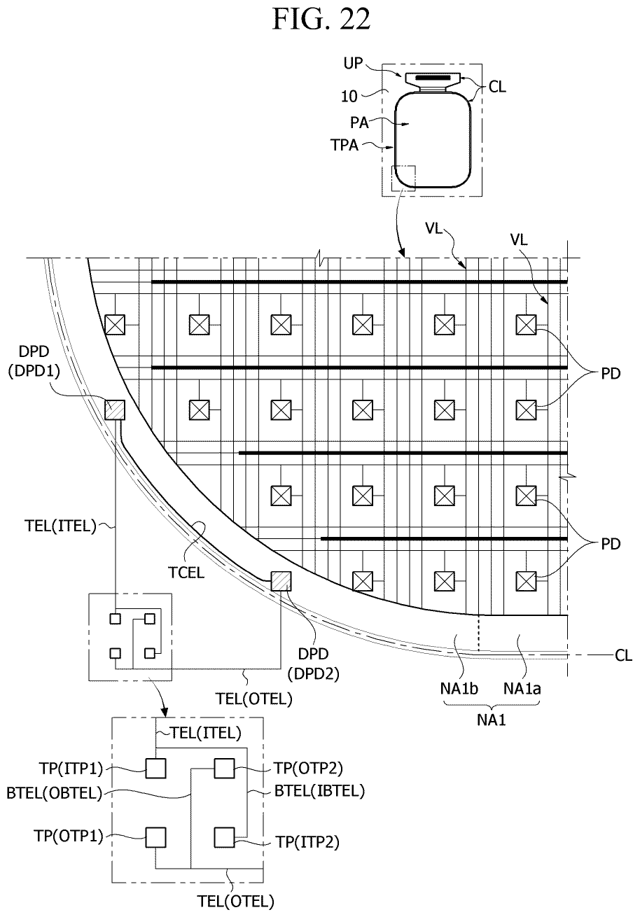

Each of the first test pad ITP and the second test pad OTP may include a first test pad TP1 on the third protection layer 114, a second test pad TP2 on the first insulation layer 115a, and a third test pad TP3 on the second insulation layer 115b (see FIG. 23), but the embodiments of the present specification are not limited thereto.

The test pads TP may be disposed in the test pad area TPA and may be used for an auto-probe test. Accordingly, it is possible to check whether the first dummy pixel driving circuit DPD1 and the second dummy pixel driving circuit DPD2 are defective, using the test pads TP, the test wires TEL, the test connection wire TCEL, and the like. For example, it is possible to check the defects in the first dummy pixel driving circuit DPD1 and the second dummy pixel driving circuit DPD2 such as internal disconnection by measuring the resistance of the first dummy pixel driving circuit DPD1, the second dummy pixel driving circuit DPD2, and the like using the test pads TP, the test wires TEL, and the test connection wire TCEL.

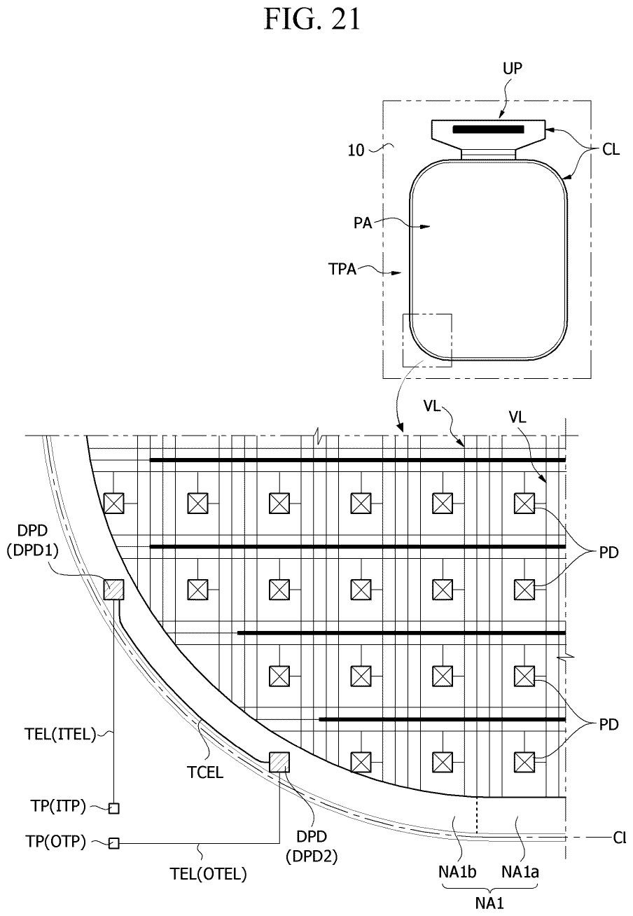

FIG. 22 is a diagram illustrating another embodiment of a disposition relationship between a half-finished panel and test pads on a mother substrate. For example, FIG. 22 is a diagram illustrating another embodiment of a disposition relationship between a half-finished panel and test pads for the display panel 100a according to the second example embodiment.

As shown in FIG. 22, the display apparatus according to the embodiment of the present specification can measure the resistance of the first dummy pixel driving circuit DPD1, the second dummy pixel driving circuit DPD2, and the like by the four-terminal resistance measurement method using measurement equipment.

The substantially same components of the two-terminal resistance measurement method illustrated in FIG. 20 and the four-terminal resistance measurement method illustrated in FIG. 21 may be represented by the same reference numbers, and detailed description thereof will not be repeated.

A plurality of half-finished panels UP, test pads TP, and the like may be implemented on a mother substrate 10, and one display panel 100a may be separated from the mother substrate 10 along a cutting line CL.

In a test pad area TPA of the mother substrate 10, third test wires BTEL that branch off from test wires TEL, respectively, may be further disposed.

The test pads TP may be disposed in the test pad area TPA. The test pads TP may include a first test pad ITP and a second test pad OTP. For example, for the four-terminal resistance measurement method, the first test pad ITP may include a first input test pad ITP1 and a second input test pad ITP2. The second test pad OTP may include a first output test pad OTP1 and a second output test pad OTP2.

Each of the first input test pad ITP1, the second input test pad ITP2, the first output test pad OTP1, and the second output test pad OTP2 may include a first test pad TP1 on the third protection layer 114, a second test pad TP2 on the first insulation layer 115a, and a third test pad TP3 on the second insulation layer 115b (see FIG. 23), but the embodiments of the present specification are not limited thereto.

The third test wires BTEL may branch off from the test wires TEL, and each of the third test wires BTEL may be connected to any one of the test pads TP to which the test wires TEL are not connected. For example, the third test wires BTEL may include an input branch test wire IBTEL that connects the first test wire ITEL and the second input test pad ITP2, and an output branch test wire OBTEL that connects the second test wire OTEL and the second output test pad OTP2. The first test wire ITEL may connect the first dummy pixel driving circuit DPD1 and the first input test pad ITP1. The second test wire OTEL may connect the second dummy pixel driving circuit DPD2 and the first output test pad OTP1.

Accordingly, the display panel 100a according to the embodiment of the present specification may include the test wires TEL disposed toward the outside such that the resistance of the dummy pixel driving circuit DPD can be measured by not only the two-terminal resistance measurement method but also the four-terminal resistance measurement method.

FIG. 23 is a diagram illustrating the resistance measurement of the first dummy pixel driving circuit and the second dummy pixel driving circuit.

The test pads TP may be electrically connected to the test wires TEL and may be used for an auto-probe test. For example, the test pads TP may include a first test pad ITP electrically connected to a first test wire ITEL and a second test pad OTP electrically connected to a second test wire OTEL.

As shown in FIG. 23, the test pad TP may include a first test pad TP1 on the third protection layer 114, a second test pad TP2 on the first insulation layer 115a, and a third test pad TP3 on the second insulation layer 115b, but the embodiments of the present specification are not limited thereto. For example, the resistance of the dummy pixel driving circuit DPD may be measured in a state in which only the first test pad TP1 electrically connected to the test wire TEL is disposed, but the present specification is not necessarily limited thereto.

An organic material layer PR in which holes are formed may be disposed on the test pads TP to guide a probe that is used for the auto-probe test. For example, the probe may be configured in a corner portion (or an edge portion) of the display panel, but the embodiments of the present specification are not limited thereto.

The organic material layer PR may include an organic insulation material. For example, the organic material layer PR may be photoresist, but the present specification is not limited thereto. For example, the organic material layer PR may be the third insulation layer 115c.

The first dummy pixel driving circuit DPD1 may be electrically connected to the first test pad ITP via the first test wire ITEL.

The second dummy pixel driving circuit DPD2 may be electrically connected to the second test pad OTP via the second test wire OTEL.

The first dummy pixel driving circuit DPD1 and the second dummy pixel driving circuit DPD2 may be connected via the test connection wire TCEL.

Accordingly, it is possible to determine whether the first dummy pixel driving circuit DPD1 and the second dummy pixel driving circuit DPD2 connected by the test connection wire TCEL are defective, by applying a current to the test pads TP via the holes in the organic material layer PR and measuring the resistance of the first dummy pixel driving circuit DPD1 and the second dummy pixel driving circuit DPD2. For example, when the first dummy pixel driving circuit DPD1 and/or the second dummy pixel driving circuit DPD2 is determined to be defective, there is a probability that the pixel driving circuits PD are defective. For this reason, it is possible to improve the process yield and the reliability of the display apparatus by stopping the progress of the manufacturing process of the display panel 100. For example, when the first dummy pixel driving circuit DPD1 and the second dummy pixel driving circuit DPD2 are not defective, the manufacturing process of the display panel 100 is performed, and the display panel 100a can be separated from the mother substrate 10 through the cutting process. An end portion of the first test wire ITEL and an end portion of the second test wire OTEL may be exposed by the cutting process along the cutting line CL.

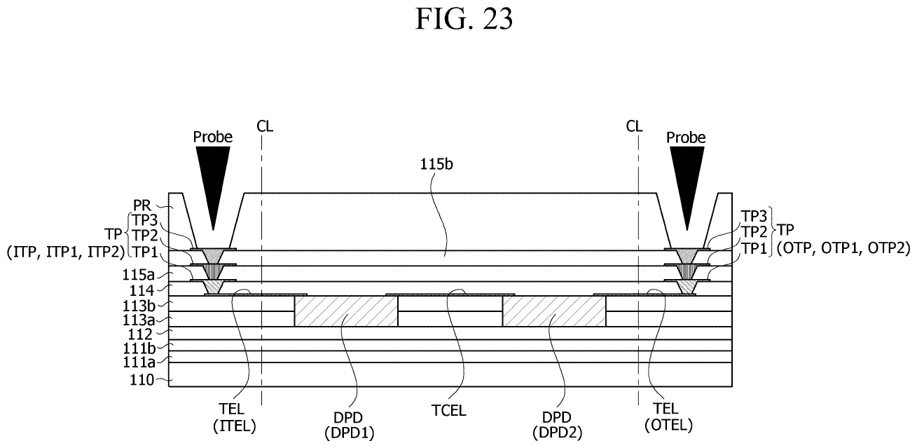

FIG. 24 is a diagram illustrating another embodiment of the display apparatus according to the embodiment of the present specification. A display panel 100b illustrated in FIG. 24 may be a display panel according to a third example embodiment.

In comparison of the display panel 100 according to the first example embodiment, the display panel 100a according to the second example embodiment, and the display panel 100b according to the third example embodiment with reference to FIGS. 8A, 8B, 13, 20, and 24, the display panel 100b according to the third example embodiment may include a first test connection wire TCEL1 and a second test connection wire TCEL2 connected to a first dummy pixel driving circuit DPD1 and a second dummy pixel driving circuit DPD2, respectively.

In describing the display panel 100b according to the third example embodiment with reference to FIGS. 8A, 8B, 13, 20, and 24, the substantially same components of the display panel 100 according to the first example embodiment, the display panel 100a according to the second example embodiment, and the display panel 100b according to the third example embodiment may be represented by the same reference numbers, and detailed description thereof will not be repeated.

The display panel 100b may include a substrate 110, a first buffer layer 111a disposed on the substrate 110, a second buffer layer 111b, an adhesive layer 112, a pixel driving circuit PD, a first protection layer 113a, a second protection layer 113b, a third protection layer 114, a first insulation layer 115a, a second insulation layer 115b, a third insulation layer 115c, a passivation layer 116, a plurality of first connection wires 121, a plurality of second connection wires 122, a plurality of signal wires TL, a plurality of communication wires NL, a plurality of first electrodes CE1, a plurality of banks BNK, a plurality of light-emitting elements ED, a plurality of second electrodes CE2, a plurality of solder patterns SDPb, a plurality of contact electrodes CCE, a first optical layer 117a, a second optical layer 117b, a third optical layer 117c, a black matrix BM, a first dummy pixel driving circuit DPD1 and a second dummy pixel driving circuit DPD2, a plurality of test wires TEL, a first test connection wire TCEL1 connected to the first dummy pixel driving circuit DPD1, a second test connection wire TCEL2 connected to the second dummy pixel driving circuit DPD2, and the like, but the embodiments of the present specification are not limited thereto. In cutting the mother substrate 10 along the cutting line CL, end portions of the test wires TEL, an end portion of the first test connection wire TCEL1, and an end portion of the second test connection wire TCEL2 may be exposed.

The first dummy pixel driving circuit DPD1 and the second dummy pixel driving circuit DPD2 may be disposed in the same layer as the pixel driving circuit PD. The first dummy pixel driving circuit DPD1 and the second dummy pixel driving circuit DPD2 may be disposed apart from the pixel driving circuit PD. For example, the pixel driving circuit PD, the first dummy pixel driving circuit DPD1, and the second dummy pixel driving circuit DPD2 may be disposed apart from each other on the adhesive layer 112.

The first dummy pixel driving circuit DPD1 and the second dummy pixel driving circuit DPD2 may be disposed apart from each other in the first non-display area NA1. For example, the first dummy pixel driving circuit DPD1 and the second dummy pixel driving circuit DPD2 may be disposed on a corner side (or an edge side) of the display panel 100b. For example, one first dummy pixel driving circuit DPD1 and one second dummy pixel driving circuit DPD2 may be disposed on the corner side (or the edge side) of the display panel 100b, but the present specification is not limited thereto.

The test wires TEL may be disposed on the adhesive layer 112 to be connected to the first dummy pixel driving circuit DPD1 and the second dummy pixel driving circuit DPD2, respectively. The test wires TEL may be disposed toward the outside from the first dummy pixel driving circuit DPD1 and the second dummy pixel driving circuit DPD2.

The test wires TEL may include a first test wire ITEL connected to the first dummy pixel driving circuit DPD1 and a second test wire OTEL connected to the second dummy pixel driving circuit DPD2. For example, a current input to the first test wire ITEL may flow through the first dummy pixel driving circuit DPD1, the test connection wire TCEL, and the second dummy pixel driving circuit DPD2 and may be output from the second test wire OTEL, but the present specification is not necessarily limited thereto. Each of an end portion of the first test wire ITEL connected to the first dummy pixel driving circuit DPD1, an end portion of the second test wire OTEL connected to the second dummy pixel driving circuit DPD2, an end portion of the first test connection wire TCEL1, and an end portion of the second test connection wire TCEL2 may be exposed. The exposed end portions of the first test wire ITEL, the second test wire OTEL, the first test connection wire TCEL1, and the second test connection wire TCEL2 may be covered with a coating layer 300.

The test connection wire TCEL may electrically connect the first dummy pixel driving circuit DPD1 and the second dummy pixel driving circuit DPD2 on the mother substrate 10. Meanwhile, when the display panel 100b is separated from the mother substrate 10 along the cutting line CL, the test connection wire TCEL may be divided into the first test connection wire TCEL1 and the second test connection wire TCEL2. Accordingly, the display panel 100b may include the first test connection wire TCEL1 and the second test connection wire TCEL2 that are spaced apart from each other and electrically separated.

The first test connection wire TCEL1 and the second test connection wire TCEL2 may be disposed in the first non-display area NA1. The first test connection wire TCEL1 and the second test connection wire TCEL2 may be disposed on the adhesive layer 112. For example, the first test connection wire TCEL1 and the second test connection wire TCEL2 may be formed of the same conductive material and through the same process as the first-first connection wire 121a, but the embodiments of the present specification are not limited thereto. For example, the first test connection wire TCEL1 and the second test connection wire TCEL2 may be formed of a conductive material having excellent such as gold (Au), silver (Ag), or aluminum (Al), but the embodiments of the present specification are not limited thereto. As another example, the first test connection wire TCEL1 and the second test connection wire TCEL2 may be formed of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto.

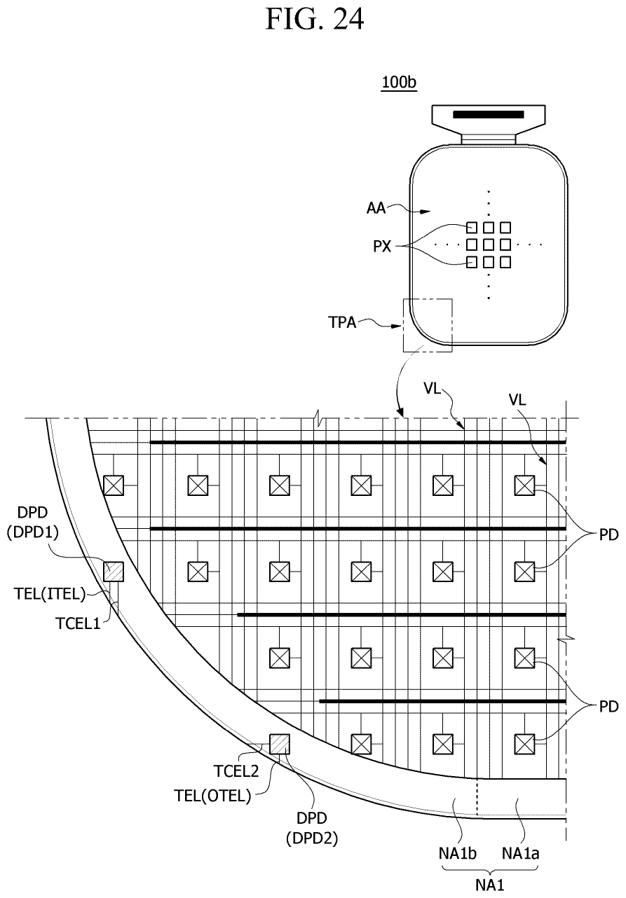

FIG. 25 is a diagram illustrating another embodiment of a disposition relationship between a half-finished panel and test pads on a mother substrate. For example, FIG. 25 is a diagram illustrating an embodiment of a disposition relationship between a half-finished panel and test pads for the display panel 100b according to the third example embodiment.

As shown in FIG. 25, the display apparatus according to the embodiment of the present specification can measure the resistance of the first dummy pixel driving circuit DPD1, the second dummy pixel driving circuit DPD2, and the like by the two-terminal resistance measurement method using measurement equipment.

A plurality of half-finished panels UP, test pads TP, and the like may be configured on a mother substrate 10. One display panel 100b may be separated from the mother substrate 10 along the cutting line CL.

The mother substrate 10 according to the embodiment of the present specification may include a panel area PA and a test pad area TPA with the cutting line CL as a reference. In the panel area PA, the half-finished panel UP may be disposed. In the test pad area TPA, a plurality of test pads TP may be disposed. The first dummy pixel driving circuit DPD1 and the second dummy pixel driving circuit DPD2 of the half-finished panel UP may be electrically connected to the test pads via the test wires TEL. For example, the test pads TP may include a first test pad ITP electrically connected to a first test wire ITEL and a second test pad OTP electrically connected to a second test wire OTEL. Accordingly, the test wires TEL may be disposed across the panel area PA and the test pad area TPA.

Each of the first test pad ITP and the second test pad OTP may include a first test pad TP1 on the third protection layer 114, a second test pad TP2 on the first insulation layer 115a, and a third test pad TP3 on the second insulation layer 115b (see FIG. 23), but the embodiments of the present specification are not limited thereto.

The test pads TP may be disposed in the test pad area TPA and may be used for an auto-probe test. Accordingly, it is possible to check whether the first dummy pixel driving circuit DPD1 and the second dummy pixel driving circuit DPD2 are defective, using the test pads TP, the test wires TEL, the test connection wire TCEL, and the like. For example, it is possible to check the defects in the first dummy pixel driving circuit DPD1 and the second dummy pixel driving circuit DPD2 such as internal disconnection by measuring the resistance of the first dummy pixel driving circuit DPD1, the second dummy pixel driving circuit DPD2, and the like using the test pads TP, the test wires TEL, and the test connection wire TCEL. The test connection wire TCEL may be divided into the first test connection wire TCEL1 and the second test connection wire TCEL2 disposed apart from each other by the cutting process.

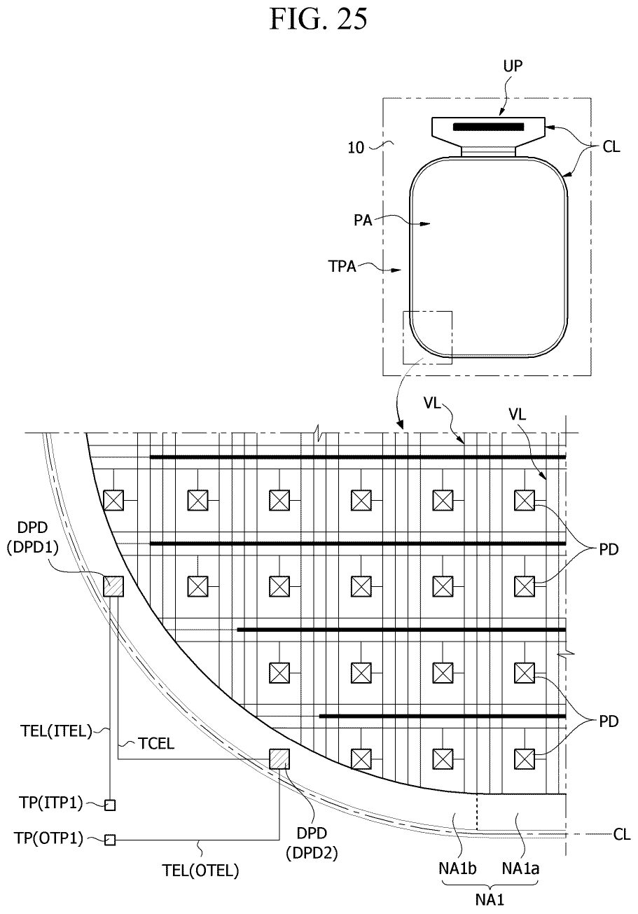

FIG. 26 is a diagram illustrating another embodiment of a disposition relationship between a half-finished panel and test pads on a mother substrate. For example, FIG. 26 is a diagram illustrating another embodiment of a disposition relationship between a half-finished panel and test pads for the display panel 100b according to the third example embodiment.

As shown in FIG. 26, the display apparatus according to the embodiment of the present specification can measure the resistance of the first dummy pixel driving circuit DPD1, the second dummy pixel driving circuit DPD2, and the like by the four-terminal resistance measurement method using measurement equipment.

In comparison of the two-terminal resistance measurement method illustrated in FIG. 25 and the four-terminal resistance measurement method illustrated in FIG. 26, the substantially same components of the two-terminal resistance measurement method illustrated in FIG. 25 and the four-terminal resistance measurement method illustrated in FIG. 26 may be represented by the same reference numbers, and detailed description will not be repeated.

A plurality of half-finished panels UP, test pads TP, and the like may be configured on a mother substrate 10. One display panel 100a may be separated from the mother substrate 10 along the cutting line CL.

In a test pad area TPA of the mother substrate 10, third test wires BTEL that branch off from test wires TEL, respectively, may be further disposed.

The test pads TP may be disposed in the test pad area TPA. The test pads TP may include a first test pad ITP and a second test pad OTP. For example, for the four-terminal resistance measurement method, the first test pad ITP may include a first input test pad ITP1 and a second input test pad ITP2. The second test pad OTP may include a first output test pad OTP1 and a second output test pad OTP2.

Each of the first input test pad ITP1, the second input test pad ITP2, the first output test pad OTP1, and the second output test pad OTP2 may include a first test pad TP1 on the third protection layer 114, a second test pad TP2 on the first insulation layer 115a, and a third test pad TP3 on the second insulation layer 115b (see FIG. 23), but the embodiments of the present specification are not limited thereto.

Each of the third test wires BTEL may branch off from the test wire TEL and may be connected to one of the test pads TP.

The third test wires BTEL may include an input branch test wire IBTEL that connects the first test wire ITEL and the second input test pad ITP2, and an output branch test wire OBTEL that connects the second test wire OTEL and the second output test pad OTP2. The first test wire ITEL may connect the first dummy pixel driving circuit DPD1 and the first input test pad ITP1. The second test wire OTEL may connect the second dummy pixel driving circuit DPD2 and the first output test pad OTP1.

Accordingly, the display panel 100b according to the embodiment of the present specification may include the test wires TEL disposed toward the outside such that the resistance of the dummy pixel driving circuit DPD can be measured by not only the two-terminal resistance measurement method but also the four-terminal resistance measurement method.

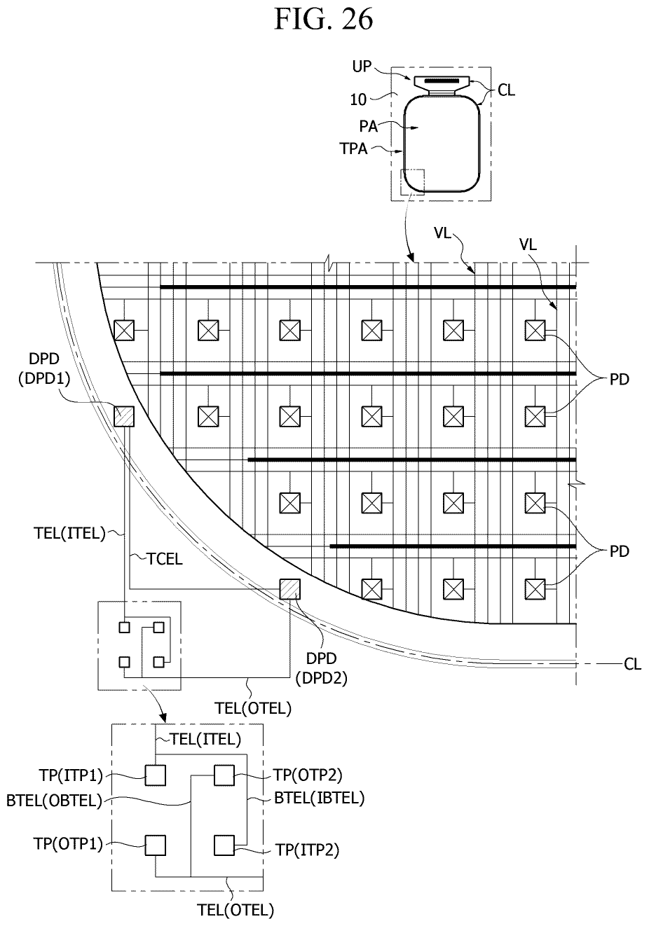

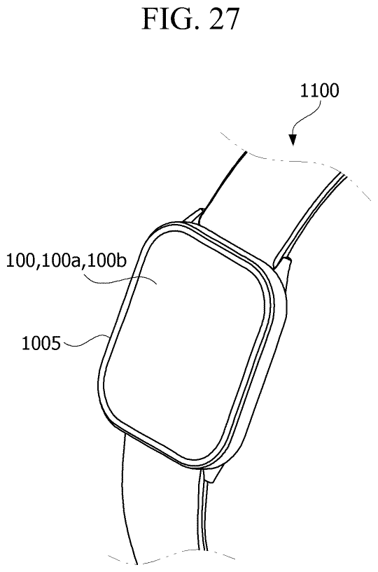

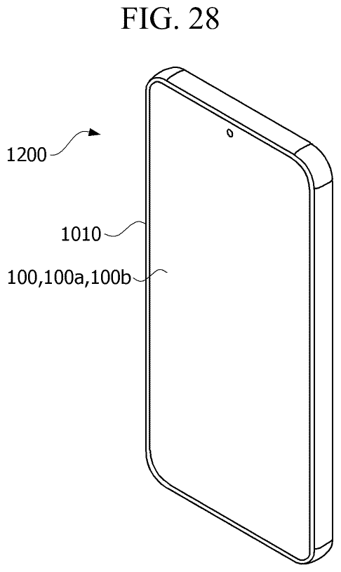

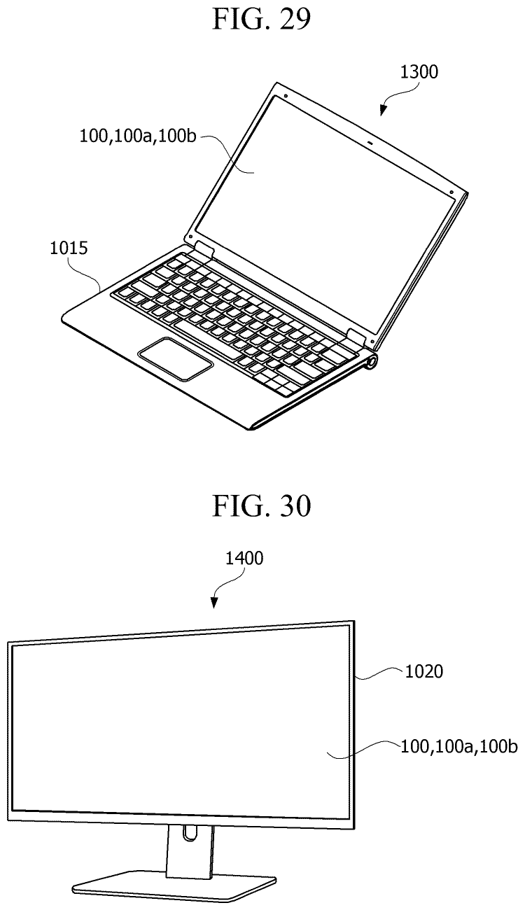

FIGS. 27 to 30 are diagrams illustrating devices to which the display device according to embodiments of the present specification is applied.

As shown in FIGS. 27 to 30, the display device 1000 according to embodiments of the present specification may be included in various devices or electronic devices. For example, as illustrated in FIGS. 27 to 30, various electronic devices may include a wearable device 1100, a mobile device 1200, a laptop 1300, and a monitor or TV 1400, but the embodiments of the present specification are not limited thereto.

Each of the wearable device 1100, the mobile device 1200, the laptop 1300, and the monitor or TV 1400 may include a casing 1005, 1010, 1015, or 1020, and the display panel 100, 100a, 100b, 100c, 100d, or 100e and the display device 1000 according to embodiments of the present specification as described in FIGS. 1 to 26.

For example, the display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation device, a vehicle display device, a theater display device, a television, a wallpaper device, a signage device, a game device, a laptop computer, a monitor, a camera, a camcorder, a home appliance, and the like.

The display device according to one or more example embodiments of the present disclosure may be described as follows.

A display apparatus according to one or more embodiments of the present specification includes a plurality of pixel driving circuits and at least one dummy pixel driving circuit disposed apart from each other on a substrate; a plurality of driving wires disposed corresponding to the plurality of pixel driving circuits; and a test wire electrically connected to the dummy pixel driving circuit.

According to one or more embodiments of the present specification, the driving wires and the test wire may be electrically separated.

According to one or more embodiments of the present specification, the display apparatus may further include light-emitting elements disposed on the substrate, in which the substrate may include a display area where the light-emitting elements are disposed and a non-display area around the display area. The pixel driving circuit may be disposed in the display area. The dummy pixel driving circuit may be disposed in the non-display area.

According to one or more embodiments of the present specification, the non-display area may include a first area and a second area, and the second area may include a curved section.

According to one or more embodiments of the present specification, the test wire may be disposed toward an outside of the pixel driving circuits.

According to one or more embodiments of the present specification, an end portion of the test wire may be exposed.

According to one or more embodiments of the present specification, the display apparatus may further include a coating layer that covers the end portion of the test wire disposed on the substrate.

According to one or more embodiments of the present specification, the test wire may include a first test wire and a second test wire connected to the one dummy pixel driving circuit.

According to one or more embodiments of the present specification, the dummy pixel driving circuit may include a first dummy pixel driving circuit and a second pixel driving circuit disposed adjacent to each other. The test wire may include a first test wire connected to the first dummy pixel driving circuit and a second test wire connected to the second dummy pixel driving circuit. The display apparatus may further include a test connection wire that connects the first dummy pixel driving circuit and the second dummy pixel driving circuit.

According to one or more embodiments of the present specification, the display apparatus may further include light-emitting elements disposed on the substrate. The substrate may include a display area where the light-emitting elements are disposed and a non-display area around the display area. The test connection wire may be disposed in the non-display area.

According to one or more embodiments of the present specification, the dummy pixel driving circuit may include a first dummy pixel driving circuit and a second pixel driving circuit disposed adjacent to each other, the display apparatus may further include a first test wire and a first test connection wire connected to the first dummy pixel driving circuit, and a second test wire and a second test connection wire connected to the second dummy pixel driving circuit.

According to one or more embodiments of the present specification, the first test connection wire and the second test connection wire may be electrically separated.

According to one or more embodiments of the present specification, an end portion of each of the first test wire, the second test wire, the first test connection wire, and the second test connection wire may be exposed.

According to one or more embodiments of the present specification, the display apparatus may further include banks disposed on the substrate; first electrodes disposed on the banks, light-emitting elements disposed on the first electrodes; and second electrodes disposed on the light-emitting elements.

According to one or more embodiments of the present specification, the display apparatus may further include a first optical layer around the light-emitting elements, and a second optical layer disposed on a side surface of the first optical layer.

According to one or more embodiments of the present specification, the display apparatus may further include signal wires disposed between the banks, in which the signal wires may include the same metal layer as the first electrodes.

According to one or more embodiments of the present specification, the light-emitting elements may be micro LEDs.

According to one or more embodiments of the present specification, the light-emitting elements may have a vertical structure.

According to one or more embodiments of the present specification, the display apparatus may further include an insulation layer disposed on the plurality of pixel driving circuits and the at least one dummy pixel driving circuit; a passivation layer that is disposed on the insulation layer and includes holes; and pattern layers connected to the first electrodes and disposed in the holes. The first electrodes and the light-emitting elements may be electrically connected via the pattern layers by eutectic bonding.

According to one or more embodiments of the present specification, the display apparatus may further include a protection layer disposed between the pixel driving circuits disposed in an outer portion among the plurality of pixel driving circuits and the dummy pixel driving circuit; and a plurality of connection wires that electrically connect the pixel driving circuits and the first electrodes. One of the plurality of connection wires may overlap the protection layer.

According to one or more embodiments of the present specification, the display apparatus may further a plurality of connection wires that electrically connect the pixel driving circuits and the first electrodes. The substrate may include a display area where the light-emitting elements are disposed and a non-display area around the display area. The pixel driving circuits may be disposed in the display area. The dummy pixel driving circuit may be disposed in the non-display area. The connection wires may be disposed along the outer portion of the display area.

According to one or more embodiments of the present specification, the display apparatus may further include a protection wire disposed along an outer portion of the display area. The protection wire may include a conductive material.

According to one or more embodiments of the present specification, the display apparatus may further include first electrodes disposed on the substrate; light-emitting elements disposed on the first electrodes; second electrodes disposed on the light-emitting elements; and connection wires that electrically connect the pixel driving circuits and the first electrodes. The connection wire may be configured with the protection wire.

A display apparatus according to one or more embodiments of the present specification may include a plurality of pixel driving circuits and at least one dummy pixel driving circuit disposed apart from each other on a substrate; a plurality of driving wires disposed corresponding to the plurality of pixel driving circuits; and two lines electrically connected to the one dummy pixel driving circuit. An end portion of each of the two lines is exposed.

According to one or more embodiments of the present specification, the driving wires and the two lines may be electrically separated.

According to one or more embodiments of the present specification, the display apparatus may further include light-emitting elements disposed on the substrate, in which the substrate may include a display area where the light-emitting elements are disposed and a non-display area around the display area. The pixel driving circuits may be disposed in the display area. The dummy pixel driving circuit and the two lines may be disposed in the non-display area.

According to one or more embodiments of the present specification, the light-emitting elements may be micro LEDs and may have a vertical structure.

According to one or more embodiments of the present specification, the dummy pixel driving circuit may include a first dummy pixel driving circuit and a second dummy pixel driving circuit disposed adjacent to each other. The two lines connected to the first dummy pixel driving circuit may include a first test wire and a first test connection wire. The two lines connected to the second dummy pixel driving circuit may include a second test wire and a second test connection wire.

According to one or more embodiments of the present specification, the first test connection wire and the second test connection wire may be electrically separated.

A display apparatus according to one or more embodiments of the present specification includes a plurality of pixel driving circuits, at least one first dummy pixel driving circuit, and at least one second dummy pixel driving circuit disposed apart from each other; a plurality of driving wires disposed corresponding to the plurality of pixel driving circuits; and two lines connected to the one first dummy pixel driving circuit, in which one line of the two lines connects the first dummy pixel driving circuit and the second dummy pixel driving circuit, and an end portion of the other line of the two lines is exposed.

According to one or more embodiments of the present specification, the driving wires and the two lines may be electrically separated.

According to one or more embodiments of the present specification, the display apparatus may further include light-emitting elements disposed on the substrate, in which the substrate may include a display area where the light-emitting elements are disposed and a non-display area around the display area. The pixel driving circuits may be disposed in the display area. The first dummy pixel driving circuit, the second dummy pixel driving circuit, and the two lines may be disposed in the non-display area.

According to one or more embodiments of the present specification, the display apparatus may further include first electrodes disposed on the substrate; light-emitting elements disposed on the first electrodes; and second electrodes disposed on the light-emitting elements. The light-emitting elements may be electrically connected to the first electrodes by eutectic bonding.

The objects to be achieved by the present disclosure, the means for achieving the objects, and effects of the present disclosure described above do not specify essential features of the claims, and thus, the scope of the claims is not limited to the disclosure of the present disclosure.

Although various example embodiments of the present disclosure have been described in more detail with reference to the accompanying drawings, the present disclosure is not limited thereto and may be embodied in many different forms without departing from the technical concept of the present disclosure. Therefore, the example embodiments disclosed in the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure.

### LIST OF REFERENCE NUMBERS

100, 100a, 100b: Display panel
110: Substrate
116: Passivation layer
121, 122: Connection wire
130, 140, 150: Light-emitting element
AA: Display area
BA: Bending area
PD: Pixel driving circuit
DPD: Dummy pixel driving circuit
SDP: Pattern layer
SP1, SP2, SP3: Subpixel

What is claimed is:

1. A display apparatus, comprising:
a plurality of pixel driving circuits and at least one dummy pixel driving circuit disposed apart from each other on a substrate;
a plurality of driving wires disposed corresponding to the plurality of pixel driving circuits; and
a test wire electrically connected to the dummy pixel driving circuit.

2. The display apparatus according to claim 1, wherein the plurality of driving wires and the test wire are electrically separated.

3. The display apparatus according to claim 1, further comprising:
light-emitting elements disposed on the substrate,
wherein the substrate includes a display area where the light-emitting elements are disposed and a non-display area around the display area,
wherein the pixel driving circuits are disposed in the display area, and
wherein the dummy pixel driving circuit is disposed in the non-display area.

4. The display apparatus according to claim 3, wherein the non-display area includes a first area and a second area, and
wherein the second area includes a curved section.

5. The display apparatus according to claim 1, wherein the test wire is disposed toward an outside of the pixel driving circuits.

6. The display apparatus according to claim 5, wherein an end portion of the test wire is exposed.

7. The display apparatus according to claim 6, further comprising:
a protection layer that covers the end portion of the test wire disposed on the substrate.

8. The display apparatus according to claim 1, wherein the test wire includes a first test wire and a second test wire connected to the at least one dummy pixel driving circuit.

9. The display apparatus according to claim 1, wherein the dummy pixel driving circuit includes a first dummy pixel driving circuit and a second dummy pixel driving circuit disposed adjacent to each other,
wherein the test wire includes a first test wire connected to the first dummy pixel driving circuit and a second test wire connected to the second dummy pixel driving circuit, and
wherein the display apparatus further comprises a test connection wire that connects the first dummy pixel driving circuit and the second dummy pixel driving circuit.

10. The display apparatus according to claim 9, further comprising:
light-emitting elements disposed on the substrate,
wherein the substrate includes a display area where the light-emitting elements are disposed and a non-display area around the display area, and
wherein the test connection wire is disposed in the non-display area.

11. The display apparatus according to claim 1, wherein the dummy pixel driving circuit includes a first dummy pixel driving circuit and a second dummy pixel driving circuit disposed adjacent to each other, and
wherein the display apparatus further comprises a first test wire and a first test connection wire connected to the first dummy pixel driving circuit, and a second test wire and a second test connection wire connected to the second dummy pixel driving circuit.

12. The display apparatus according to claim 11, wherein the first test connection wire and the second test connection wire are electrically separated.

13. The display apparatus according to claim 11, wherein an end portion of each of the first test wire, the second test wire, the first test connection wire, and the second test connection wire is exposed.

14. The display apparatus according to claim 1, further comprising:
banks disposed on the substrate;
first electrodes disposed on the banks;
light-emitting elements disposed on the first electrodes; and
second electrodes disposed on the light-emitting elements.

15. The display apparatus according to claim 14, further comprising:
a first optical layer around the light-emitting elements; and
a second optical layer disposed on a side surface of the first optical layer.

16. The display apparatus according to claim 14, further comprising:
signal wires disposed between the banks,
wherein the signal wires include a same metal layer as the first electrodes.

17. The display apparatus according to claim 14, wherein the light-emitting elements are micro LEDs.

18. The display apparatus according to claim 14, wherein the light-emitting elements have a vertical structure.

19. The display apparatus according to claim 14, further comprising:
an insulation layer disposed on the plurality of pixel driving circuits and the at least one dummy pixel driving circuit;
a passivation layer that is disposed on the insulation layer and includes holes; and
pattern layers connected to the first electrodes and disposed in the holes,
wherein the first electrodes and the light-emitting elements are electrically connected via the pattern layer by eutectic bonding.

20. The display apparatus according to claim 14, further comprising:
a protection layer that is disposed between the pixel driving circuits disposed in an outer portion among the plurality of pixel driving circuits and the dummy pixel driving circuit; and
a plurality of connection wires that electrically connect the pixel driving circuits and the first electrodes,
wherein one of the plurality of connection wires overlaps the protection layer.

21. The display apparatus according to claim 20, further comprising:
a plurality of connection wires that electrically connect the pixel driving circuits and the first electrodes,
wherein the substrate includes a display area where the light-emitting elements are disposed and a non-display area around the display area,
wherein the pixel driving circuits are disposed in the display area,
wherein the dummy pixel driving circuit is disposed in the non-display area, and
wherein the connection wires are disposed along the outer portion of the display area.

22. The display apparatus according to claim 3, further comprising:
a protection wire disposed along an outer portion of the display area,
wherein the protection wire includes a conductive material.

23. The display apparatus according to claim 22, further comprising:
a plurality of first electrodes disposed on the substrate;
a plurality of light-emitting elements disposed on the first electrodes;
a plurality of second electrodes disposed on the light-emitting elements; and
a plurality of connection wires that electrically connect the pixel driving circuits and the first electrodes,
wherein the connection wires are configured with the protection wire.

24. A display apparatus, comprising:
a plurality of pixel driving circuits and at least one dummy pixel driving circuit disposed apart from each other on a substrate;
a plurality of driving wires disposed corresponding to the plurality of pixel driving circuits; and
at least two lines electrically connected to the at least one dummy pixel driving circuit,
wherein an end portion of each of the at least two lines is exposed.

25. The display apparatus according to claim 24, wherein the plurality of driving wires and the two lines are electrically separated.

26. The display apparatus according to claim 24, further comprising:
light-emitting elements disposed on the substrate,
wherein the substrate includes a display area where the light-emitting elements are disposed and a non-display area around the display area,
wherein the pixel driving circuits are disposed in the display area, and
wherein the dummy pixel driving circuit and the at least two lines are disposed in the non-display area.

27. The display apparatus according to claim 26, wherein the light-emitting elements are micro LEDs and have a vertical structure.

28. The display apparatus according to claim 24, wherein the dummy pixel driving circuit includes a first dummy pixel driving circuit and a second dummy pixel driving circuit disposed adjacent to each other,
wherein the at least two lines include a first test wire and a first test connection wire which are connected to the first dummy pixel driving circuit, and
wherein the at least two lines include a second test wire and a second test connection wire which are connected to the second dummy pixel driving circuit.

29. The display apparatus according to claim 28, wherein the first test connection wire and the second test connection wire are electrically separated.

30. A display apparatus, comprising:
a plurality of pixel driving circuits, at least one first dummy pixel driving circuit, and at least one second dummy pixel driving circuit disposed apart from each other on a substrate;
a plurality of driving wires disposed corresponding to the plurality of pixel driving circuits; and
two lines connected to the at least one first dummy pixel driving circuit,
wherein one of the two lines connects the first dummy pixel driving circuit and the second dummy pixel driving circuit, and
wherein an end portion of the other of the two lines is exposed.

31. The display apparatus according to claim 30, wherein the driving wires and the two lines are electrically separated.

32. The display apparatus according to claim 30, further comprising:
light-emitting elements disposed on the substrate,
wherein the substrate includes a display area where the light-emitting elements are disposed and a non-display area around the display area,
wherein the plurality of pixel driving circuits are disposed in the display area, and
wherein the first dummy pixel driving circuit, the second dummy pixel driving circuit, and the two lines are disposed in the non-display area.

33. The display apparatus according to claim 30, further comprising:
first electrodes disposed on the substrate;
light-emitting elements disposed on the first electrodes; and
second electrodes disposed on the light-emitting elements,
wherein the light-emitting elements are electrically connected to the first electrodes by eutectic bonding.
